(19) United States
(12) Patent Application Publication
(10) Pub. No.: US 2024/0282794 A1
(43) Pub. Date: Aug. 22, 2024

(54) PYRAMIDAL STRUCTURE FOR PLENOPTIC PIXEL

(71) Applicants: InterDigital CE Patent Holdings, SAS, Paris (FR); Commissariat à l'Energie Atomique et aux Energies Alternatives, Paris (FR)

(72) Inventors: Guillaume Chataignier, Cesson-Sevigne (FR); Benoit Vandame, Betton (FR); Jérôme Vaillant, Grenoble (FR)

(21) Appl. No.: 18/291,181

(22) PCT Filed: Jul. 19, 2022
(86) PCT No.: PCT/EP2022/070209

§ 371 Date: Jan. 22, 2024

(30) Foreign Application Priority Data
Jul. 26, 2021 (EP) 21306035.3

(51) Int. Cl. H01L 27/146

(52) U.S. Cl. CPC H01L 27/14627; H01L 27/14621

(57) ABSTRACT

Some embodiments of an apparatus, for example a light-field apparatus, may include a microlens; a color filter system; and two or more plenoptic subpixel sensors, the two or more plenoptic subpixel sensors comprising two or more photodiodes formed in a silicon layer, wherein a pyramid shape is etched in the two or more respective silicon photodiodes formed in the silicon layer.

### CROSS-REFERENCE TO RELATED APPLICATIONS

The present application is an International Application, which claims benefit of European Patent Application No. EP21306035, entitled “PYRAMIDAL STRUCTURE FOR PLENOPTIC PIXEL,” filed Jul. 26, 2021, which is hereby incorporated by reference in its entirety.

### BACKGROUND

An integrated plenoptic sensor is an imaging sensor where a microlens is shared between multiple subpixels. An integrated plenoptic sensor records a “4D light-field” which may give indications on the angle of incidence of light. An integrated plenoptic sensor may be used on cameras and smartphones to drive the autofocus of the main lens. An integrated plenoptic sensor may provide additional abilities, such as passive depth mapping, refocusing, or aberration correction.

The present disclosure relates to plenoptic cameras. A plenoptic camera is similar to a common camera with a lens system and alight sensor, with the addition of a micro-lens array over the micro-image sensor. Each micro-lens produces a micro-image on the sensor. The resulting plenoptic image may be referred to as a 4D light field which gives indications on the sensor and pupil coordinates of the photon trajectory. For later display and processing, the 4D light field may be processed through an operation known as projection into a 2D re-focused image. The projection operation allows for the possibility of tuning the focalization distance.

In some plenoptic cameras, each pixel of the light sensor is covered by a color filter that primarily allows light of one color to reach the corresponding pixel. In some such cameras, the color filters are arranged as a so-called Bayer filter. The conventional Bayer filter allows one color-red, green, or blue—to be recorded by each corresponding pixel. When an image has been captured using a Bayer filter, each pixel has only one associated color value, corresponding to the color of the filter associated with that pixel. From this image, it may be desirable to obtain an image in which each of the pixels has all three color values. This may be done with processing to obtain the two missing color values for each pixel. Such processing techniques are referred to as demosaicing. Demosaicing can be a non-trivial process, particularly for images or regions of images that cover highly textured areas.

Bayer color filters have been used with plenoptic cameras. To process 4D light field images captured with such cameras, demosaicing may be performed concurrently with a 2D refocusing process.

### Plenoptic Sampling of 4D Light-Field Data

Conventional plenoptic cameras 100 are similar to ordinary 2D cameras with a main lens 102 and the addition of a micro-lens array 104 set just in front of the sensor 106 as illustrated schematically in FIG. 1. The sensor pixels under each micro-lens record a respective micro-lens image.

Plenoptic cameras record 4D light-field data which can be transformed into various by-products such as re-focused images with freely selected distances of focalization.

The sensor of a light-field camera records an image which is made of a collection of 2D small images arranged within a larger 2D image. Each micro-lens in the array, and each corresponding small micro-lens image generated under that lens, may be indexed by the coordinates (i, j). The pixels of the light field may be associated to four coordinates (x, y, i, j), where (x, y) identifies the location of the pixel in the complete image. The 4D light field recorded by the sensor may be represented by L(x, y, i, j).

FIG. 2 schematically illustrates the image 200 which is recorded by the sensor. Each micro-lens produces a micro-image 202 which is schematically represented by a circle (the shape of the small image depends on the shape of the micro-lenses which is typically circular). Pixel coordinates are labelled (x, y). p 206 is the distance between two consecutive micro-images. p 206 is not necessary an integer value. Micro-lenses are chosen such that p 206 is larger than a pixel size S. Micro-lens images are referenced by their coordinate (i, j). Each micro-lens image samples the pupil of the main lens with the (u, v) coordinate system. Some pixels might not receive any photons from any micro-lens; those pixels may be disregarded. Indeed, the inter micro-lens space may be masked out to prevent photons to pass outside from a micro-lens (if the micro-lenses have a square shape, no masking is needed). The center of a micro-lens image (i, j) is located on the sensor at the coordinate (x_{i,j}, y_{i,j}). θ is the angle between the square lattice of pixel and the square lattice of micro-lenses. In FIG. 2, θ=0. Assuming the micro-lenses are arranged according to a regular square lattice, the (x_{i,j}, y_{i,j}) can be computed by the following equation considering (x_{0,0}, y_{0,0}) the pixel coordinate of the micro-lens image (0,0):

$$[ \begin{matrix}{x}_{i , j} \\ {y}_{i , j}\end{matrix} ] = p [ \begin{matrix}cos θ & - s in θ \\ sin θ & cos θ\end{matrix} ] [ \begin{matrix}i \\ j\end{matrix} ] + [ \begin{matrix}{x}_{0 , 0} \\ {y}_{0 , 0}\end{matrix} ] \qquad Eq . 1$$

FIG. 2 also illustrates that an object from the scene may be visible on several contiguous micro-lens images, with each image 204 being illustrated as a dark square dot. The distance between two consecutive views of an object is w 208. This distance w is referred to herein as the replication distance. An object is theoretically visible on r consecutive micro-lens images with

$$r = ⌊ \frac{p}{\vert p - w \vert} ⌋ \qquad Eq . 2$$

where r is the number of consecutive micro-lens images in one dimension, and └ . . . ┘ is the floor function. An object is theoretically visible in r² micro-lens images. Depending on the shape of the micro-lens image, some of the r² views of the object might be invisible.

### Optical Properties of Light-Field Cameras

The distances p and w introduced in the previous sub-section are given in unit of pixel size. They can be converted into physical unit distances (e.g., meters), respectively P and W, by multiplying them by the pixel size δ, such that W=δw and P=δp. These distances can vary depending on the light-field camera characteristics.

FIG. 3 and FIG. 4 are schematic side illustrations of different light-field cameras 300, 400 assuming a perfect thin-lens model. The main lens in these examples has a focal length F and an aperture Φ. The micro-lens array is made of micro-lenses having a focal length f. The pitch of the micro-lens array is ϕ. The micro-lens array 304, 404 is located at a distance D from the main-lens 302, 402, and a distance d from the sensor 306, 406. The object (not visible on the figures) is located at a distance z from the main-lens (toward the left). This object is focused by the main lens at a distance z′ from the main lens (toward the right). FIG. 3 illustrates the case where D>z′, and FIG. 4 illustrates the case where D<z′. In both cases, the micro-lens images can be in focus depending on d and f. FIGS. 3 and 4 illustrate examples of so-called type II plenoptic cameras.

In an alternative light-field camera design referred to as a type I plenoptic camera 500, the parameters are selected such that focal length f=d, the distance between the micro-lens array 504 and the sensor 506. An example of such a design is illustrated in FIG. 5. This design is made such that the main-lens 502 is focusing images close to the micro-lens array 504. If the main-lens 502 is focusing exactly on the micro-lens array 504, then W=∞. Also, the micro-lens images are fully out-of-focus and equal to a constant (not considering noise).

The replication distance W varies with the z, the distance of the object. To establish the relation between W and z, one may refer to the thin lens equation

$$\frac{1}{z} + \frac{1}{{z}^{′}} = \frac{1}{F} \qquad Eq . 3$$

### and to Thales law

$$\frac{D - {z}^{′}}{ϕ} = \frac{D - {z}^{′} + d}{W} \qquad Eq . 4$$

Combining the previous two equations, one can deduce

$$W = ϕ ( 1 + \frac{d}{D - \frac{z F}{z - F}} ) \qquad Eq . 5$$

The relation between W and z does not assume that the micro-lens images are in focus. Micro-lens images may be in focus when thin lens equation is satisfied such that

$$\frac{1}{D - {z}^{′}} + \frac{1}{d} = \frac{1}{f} \qquad Eq . 6$$

Also from the Thales law one derives P as follows.

$$e = \frac{D + d}{D} \qquad Eq . 7$$

$$P = ϕe$$

The ratio e defines the enlargement between the micro-lens pitch and the micro-lens images pitch. This ratio is very close to 1 since D>>d.

### Sub-Aperture Images

Some of the plenoptic cameras as described above have the following properties: the micro-lens array has a square lattice (like the pixel array) and has no rotation versus the pixels; and the micro-lens image diameter is equal to an integer number of pixels (or almost equal to an integer number of pixels). These properties are satisfied by most feasible plenoptic sensors. These properties allow for the generation of images known as sub-aperture images.

A sub-aperture image collects all of the 4D light-field pixels having the same relative position within their respective micro-lens image, for example all of the pixels having the same (u, v) coordinates. If the array of micro-lenses has the size I×J, then each sub-aperture image also has size I×J. And if there is a p×p array of pixels under each micro-lens, then there are p×p sub-aperture images. If the number of pixels of the sensor is Nₓ×N_{y}, then each sub-aperture image may have the size of Nₓ/p×N_{y}/p.

FIGS. 6A-6B schematically illustrate a conversion from a captured light-field image L(x, y, i, j) into a series of sub-aperture images S(α, β, u, v). FIG. 6A illustrates alight-field image 600 (with size 24×16 pixels in this simplified example, although real-world examples generally include many more pixels), with each pixel position being given by coordinates (x, y). Each of the micro-lenses 602 (illustrated schematically by a circle) is associated with a 4×4 micro-image, with positions in the micro-image being given by coordinates (α, β The micro-images are arranged in a 6×4 array, with each micro-image being indexed by coordinates (i, j). As seen in FIG. 6A, an object 604 (represented by a solid round dot) is imaged in nine of the micro-images.

FIG. 6B illustrates a set 650 of sixteen, i.e. 4×4, sub-aperture images 652 generated from the light field of FIG. 6A. Each sub-aperture image 652 has a size of I×J pixels (6×4 in this simplified example, corresponding to the number of micro-images). A position within each sub-aperture image is indicated by coordinates (α, β), where 0≤α<I and 0≤β<J. Each 2D sub-aperture image 652 may be identified by pupil coordinates (u, v) and denoted by S(u, v).

An example of generating a sub-aperture image from a light-field image is as follows. In FIG. 6A, the top-left pixel of each micro-image within the light-field image is shaded. All of these pixels are combined into a single sub-aperture image, namely the sub-aperture image 652 at the top-left of FIG. 6B.

The relations between (x, y, i,j) and (a, p, u, v) may be expressed as follows:

$$( α , β , u , v ) = ( ⌊ \frac{x}{p} ⌋ , ⌊ \frac{y}{p} ⌋ , x mod p , y mod p ) \qquad Eq . 8$$

where └·┘ denotes the floor function, and mod denotes the modulo function.

If p is not exactly an integer but close to an integer, then the sub-aperture images can be computed by considering the distance between the micro-lens image equal to └p┘ the integer just greater than p. This case occurs especially when the micro-lens diameter ϕ is equal to an integer number of pixels. In the case, p=ϕe being slightly larger than ϕ since e=(D+d)/d is slightly greater than 1. The advantage of considering └p┘ is that the sub-aperture images are computed without interpolation since one pixel L(x, y, i, j) corresponds to an integer coordinate sub-aperture pixel S(α, β, u, v). The drawback is that the portion of the pupil from which photons are recorded is not constant within a given sub-aperture image S(u, v). As a result, S(u, v) sub-aperture image is not exactly sampling the (u, v) pupil coordinate.

In cases where p is not an integer, or where the micro-lens array is rotated versus the pixel array, then the sub-aperture images may be computed using interpolation since the centers (x_{i,j}, u_{i,j}) of the micro-lenses are not at integer coordinates.

Within the light-field image L(x, y, i,j) an object is made visible on several micro-images with a replication distance w. On the sub-aperture images, an object is also visible several times. From one sub-aperture image to the next horizontal one, an object coordinate (α, β) appears shifted by the disparity p. The relation between ρ and w can be expressed by:

$$ρ = \frac{1}{w - p} \qquad Eq . 9$$

Also, it is possible to establish a relation between the disparity p and the distance z of the object by combining equations (5) and (9):

$$ρ = \frac{δ D}{ϕ d} ( \frac{D}{{z}^{′}} - 1 ) \qquad Eq . 10$$

### Projecting Light-Field Pixels on a Re-Focus Image.

Image refocusing consists in projecting the light-field pixels L(x, y, i,j) recorded by the sensor into a 2D refocused image of coordinate (X, Y). The projection may be performed by shifting the micro-images (i, j):

$$[ \begin{matrix}X \\ Y\end{matrix} ] = s [ \begin{matrix}x \\ y\end{matrix} ] - s {w}_{f ocus} [ \begin{matrix}i \\ j\end{matrix} ] \qquad Eq . 11$$

where w_{focus} is the selected replication distance corresponding to z_{focus} the distance of the objects that appear in focus in the computed refocused image. s is a zoom factor which controls the size of the refocused image. The value of the light-field pixel L(x, y, i, j) is added on the refocused image at coordinate (X, Y). If the projected coordinate is non-integer, the pixel is added using interpolation. To record the number of pixels projected into the refocus image, a weight-map image having the same size as the refocus image is created. This image is preliminary set to 0. For each light-field pixel projected on the refocused image, the value of 1.0 is added to the weight-map at the coordinate (X, Y). If interpolation is used, the same interpolation kernel is used for both the refocused and the weight-map images. After all of the light-field pixels are projected, the refocused image is divided pixel per pixel by the weight-map image. This normalization step provides for brightness consistency of the normalized refocused image.

### Addition of the Sub-Aperture Images to Compute the Re-Focus Image.

In another technique of performing refocusing, the refocused images can be computed by summing-up the sub-aperture images S(α, β) taking into consideration the disparity ρ_{focus} for which objects at distance z_{focus} are in focus.

$$[ \begin{matrix}X \\ Y\end{matrix} ] = s [ \begin{matrix}α \\ β\end{matrix} ] + s {ρ}_{fo cus} [ \begin{matrix}u \\ v\end{matrix} ] \qquad Eq . 12$$

The sub-aperture pixels are projected on the refocused image, and a weight-map records the contribution of this pixel, following the same procedure described above.

### SUMMARY

An example apparatus in accordance with some embodiments may include a microlens; and two or more plenoptic subpixel sensors, the two or more plenoptic subpixel sensors including two or more photodiodes formed in a silicon layer, wherein a pyramidal structure is etched in the two or more respective silicon photodiodes formed in the silicon layer.

For some embodiments of the example apparatus, the pyramidal structure may be formed to generate an optical prism deviating light away from a center of the two or more plenoptic subpixel sensors.

For some embodiments of the example apparatus, the pyramidal structure may be configured to reduce optical crosstalk between at least two of the two or more plenoptic subpixel sensors.

For some embodiments of the example apparatus, the pyramidal structure may be configured to increase sensitivity of at least one of the two or more plenoptic subpixel sensors.

For some embodiments of the example apparatus, the pyramidal structure may be configured to increase angular discrimination for light incident on the microlens at an angle near a chief ray angle of the microlens.

For some embodiments of the example apparatus, the pyramid structure may be configured to confine light to one of the two or more plenoptic subpixel sensors.

For some embodiments of the example apparatus, the pyramid structure may be configured to reflect light away from at least one of the two or more plenoptic subpixel sensors.

For some embodiments of the example apparatus, the silicon layer may be etched with a trench conforming to a deep trench isolation (DTI) structure.

For some embodiments of the example apparatus, a focal length of the microlens may be less than a threshold.

For some embodiments of the example apparatus, the two or more plenoptic sensors may include a dual pixel sensor; and the pyramidal structure may include a triangular structure.

For some embodiments of the example apparatus, the two or more plenoptic sensors may include a quad pixel sensor.

For some embodiments of the example apparatus, the pyramidal structure may include a material layer above the silicon layer.

For some embodiments of the example apparatus, the pyramidal structure may conform to pyramid-shaped trenches etched in the silicon layer.

Some embodiments of the example apparatus may further include a color filter system.

For some embodiments of the example apparatus, the pyramidal structure may include a material layer above the silicon layer; and the material layer may include an oxide layer between the color filter system and at least one of the two or more plenoptic subpixel sensors.

For some embodiments of the example apparatus, the pyramidal structure may further include a color filter layer of the color filter system above the material layer.

For some embodiments of the example apparatus, the color filter layer may include a color filter resin.

For some embodiments of the example apparatus, the color filter system may include a planarization layer and a color filter layer.

For some embodiments of the example apparatus, a horizontal facet angle of the pyramidal structure may be 54.7 degrees.

For some embodiments of the example apparatus, a base of the pyramidal structure may be equal to half of a diameter of the microlens.

For some embodiments of the example apparatus, the two or more plenoptic subpixel sensors may be arranged in a 2×1 grid, and the pyramidal structure may be centered on a line dividing the 2×1 grid in half.

For some embodiments of the example apparatus, the two or more plenoptic subpixel sensors may be arranged in a 2×2 grid, and the pyramidal structure may be centered on a center of the 2×2 grid.

For some embodiments of the example apparatus, the two or more plenoptic subpixel sensors may be arranged in a 3×3 grid, and the pyramidal structure may be centered on a center of the 3×3 grid.

For some embodiments of the example apparatus, the pyramidal structure may be a frustum, and a flat top of the frustum may be configured to match a center subpixel sensor of the 3×3 grid.

For some embodiments of the example apparatus, a tip of the pyramidal structure may be a square.

For some embodiments of the example apparatus, a base of the pyramidal structure may be a disk.

For some embodiments of the example apparatus, a tip of the pyramidal structure may be a disk.

For some embodiments of the example apparatus, the two or more plenoptic subpixel sensors may be arranged in a grid array, and the pyramidal structure may be centered on a center of the grid array.

For some embodiments of the example apparatus, a pyramid portion of the pyramidal structure may be a triangle extruded in at least one direction.

For some embodiments of the example apparatus, a pyramid portion of the pyramidal structure may be a polygon extruded in at least one direction.

For some embodiments of the example apparatus, a base of a pyramid portion of the pyramidal structure may be a square.

Some embodiments of the example apparatus may further include one or more external insulators adjacent to an external edge of at least one of the plenoptic subpixel sensors.

For some embodiments of the example apparatus, the microlens may be configured to shift a chief ray angle corresponding to a pixel offset of two pixels.

For some embodiments of the example apparatus, at least one of the two or more plenoptic subpixel sensors may be adjacent to the color filter system.

Some embodiments of the example apparatus may further include an oxide layer, wherein the oxide layer may be adjacent to the color filter system, wherein at least one of the two or more plenoptic subpixel sensors may be adjacent to the oxide layer, and wherein the oxide layer may be between the color filter system and at least one of the two or more plenoptic subpixel sensors.

For some embodiments of the example apparatus, a base of a pyramid portion of the pyramidal structure may be adjacent to the oxide layer.

For some embodiments of the example apparatus, a size of a base of a pyramid portion of the pyramidal structure may be adjusted based on a curvature of the microlens.

For some embodiments of the example apparatus, the pyramidal structure may be symmetrical along a first plane cutting through a center of the pyramidal structure, the pyramidal structure may be symmetrical along a second plane cutting through the center of the pyramidal structure, and wherein the first plane may be perpendicular to the second plane.

For some embodiments of the example apparatus, wherein the color filter system may be adjacent to the microlens.

For some embodiments of the example apparatus, two or more plenoptic subpixel sensors may be adjacent to the color filter system.

For some embodiments of the example apparatus, the color filter system may include a filter pattern of two or more subpixels.

For some embodiments of the example apparatus, the pyramidal structure may include silicon dioxide (SiO₂).

For some embodiments of the example apparatus, the pyramidal structure may include silicon oxide.

For some embodiments of the example apparatus, the pyramidal structure may be configured to reduce optical crosstalk between at least two pixels.

For some embodiments of the example apparatus, the pyramidal structure may be configured to reduce optical crosstalk between at least two microlenses.

### BRIEF DESCRIPTION OF THE DRAWINGS

FIG. 1 is a schematic illustration of an example plenoptic camera.

FIG. 2 is a schematic illustration of example light field data recorded by a plenoptic sensor.

FIG. 3 is a schematic illustration of the parameters of a plenoptic type II camera with W>P.

FIG. 4 is a schematic illustration of the parameters of a plenoptic type II camera with W<P.

FIG. 5 is a schematic illustration of the parameters of a plenoptic type I camera with f=d.

FIGS. 6A-6B are schematic illustrations of conversion of light-field pixels into sub-aperture images.

FIG. 7 is a system diagram illustrating an example wireless transmit/receive unit (WTRU) that may be used to capture and/or process plenoptic images according to some embodiments.

FIG. 8A is a schematic side view illustrating an example quad pixel according to some embodiments.

FIG. 8B is a schematic plan view illustrating an example quad pixel according to some embodiments.

FIG. 9A is a schematic plan view illustrating an example sub aperture image (SAI) pattern for an array of quad pixels according to some embodiments.

FIG. 9B is a schematic plan view illustrating example sub aperture images (SAIs) according to some embodiments.

FIG. 10A is a schematic side view illustrating an example diffraction pattern inside a pixel for light entering at normal incidence according to some embodiments.

FIG. 10B is a schematic side view illustrating an example diffraction pattern inside a pixel for light entering at an off-angle according to some embodiments.

FIGS. 11A to 11D are schematic plan views illustrating example sub aperture images A to D for an out-of-focus white spot without diffraction according to some embodiments.

FIG. 11E is a schematic plan view illustrating an example summation of sub aperture images A to D in FIGS. 5A to 5D according to some embodiments.

FIGS. 11F to 111 are schematic plan views illustrating example sub aperture images A to D for an out-of-focus white spot with diffraction according to some embodiments.

FIG. 11J is a schematic plan view illustrating an example summation of sub aperture images A to D in FIGS. 11F to 111 according to some embodiments.

FIG. 12 is a schematic side view illustrating an example crosstalk between microlenses according to some embodiments.

FIGS. 13A-13E are schematic plan views illustrating an example Chief Ray Angle correction via a microlens shift according to some embodiments.

FIG. 14A is a graph illustrating example left and right photo detect (PD) signals (P_{abs}_{_{left}}, P_{abs}_{_{right}}) vs. angle of incidence according to some embodiments.

FIG. 14B is a graph illustrating an example ratio of left and right PD signals

$$( \frac{{P}_{{abs}_{left}}}{{P}_{{abs}_{right}}} )$$

vs. angle of incidence according to some embodiments.

FIG. 15A is a schematic side view illustrating an example low angle of incidence for a quad pixel without a pyramid shape etched in the silicon according to some embodiments.

FIG. 15B is a schematic side view illustrating an example higher angle of incidence for a quad pixel without a pyramid shape etched in the silicon according to some embodiments.

FIG. 15C is a schematic side view illustrating an example low angle of incidence for a quad pixel with a pyramid shape etched in the silicon according to some embodiments.

FIG. 15D is a schematic side view illustrating an example higher angle of incidence for a quad pixel with a pyramid shape etched in the silicon according to some embodiments.

FIG. 16A is a graph illustrating example left and right photo detect (PD) signals (P_{abs}_{_{left}}, P_{abs}_{_{right}}) vs. angle of incidence for a 3.5 μm quad pixel without a pyramid shape etched in the silicon according to some embodiments.

FIG. 16B is a graph illustrating an example ratio of left and right PD signals

$$( \frac{{P}_{{abs}_{left}}}{{P}_{{abs}_{rig}}} )$$

and a threshold vs. angle of incidence for a 3.5 μm quad pixel without a pyramid shape etched in the silicon according to some embodiments.

FIG. 17A is a graph illustrating example left and right photo detect (PD) signals (P_{abs}_{_{left}}, P_{abs}_{_{right}}) vs. angle of incidence for a 3.5 μm quad pixel with a pyramid shape etched in the silicon according to some embodiments.

FIG. 17B is a graph illustrating an example ratio of left and right PD signals

$$( \frac{{P}_{{abs}_{left}}}{{P}_{{abs}_{right}}} )$$

and a threshold vs. angle of incidence for a 3.5 μm quad pixel with a pyramid shape etched in the silicon according to some embodiments.

FIG. 18A is a graph illustrating example left and right photo detect (PD) signals (P_{abs}_{_{left}}, P_{abs}_{_{right}}) vs. angle of incidence for a 1.6 μm quad pixel without a pyramid shape etched in the silicon according to some embodiments.

FIG. 18B is a graph illustrating an example ratio of left and right PD signals

$$( \frac{{P}_{{abs}_{left}}}{{P}_{{abs}_{right}}} )$$

and a threshold vs. angle of incidence for a 1.6 μm quad pixel without a pyramid shape etched in the silicon according to some embodiments.

FIG. 19A is a graph illustrating example left and right photo detect (PD) signals (P_{abs}_{_{left}}, P_{abs}_{_{right}}) vs. angle of incidence for a 1.6 μm quad pixel with a pyramid shape etched in the silicon according to some embodiments.

FIG. 19B is a graph illustrating an example ratio of left and right PD signals

$$( \frac{{P}_{{abs}_{left}}}{{P}_{{abs}_{right}}} )$$

and a threshold vs. angle of incidence for a 1.6 μm quad pixel with a pyramid shape etched in the silicon according to some embodiments.

FIG. 20A is a schematic plan view illustrating an example pyramid for a dual pixel according to some embodiments.

FIG. 20B is a schematic side view illustrating an example pyramid for a dual pixel according to some embodiments.

FIG. 21A is a schematic plan view illustrating an example pyramid for a quad pixel according to some embodiments.

FIG. 21B is a schematic side view illustrating an example pyramid for a quad pixel according to some embodiments.

FIG. 22A is a schematic plan view illustrating an example pyramid for a nona pixel according to some embodiments.

FIG. 22B is a schematic side view illustrating an example pyramid for a nona pixel according to some embodiments.

FIG. 23A is a schematic plan view illustrating an example pyramid for a 45° square based pyramidal structure according to some embodiments.

FIG. 23B is a schematic plan view illustrating an example pyramid for a disk based pyramidal structure according to some embodiments.

FIG. 23C is a schematic side view illustrating an example pyramid for a pyramidal structure with a curved convex facet according to some embodiments.

FIG. 23D is a schematic side view illustrating an example pyramid for a pyramidal structure with a curved concave facet according to some embodiments.

FIG. 24A is a schematic side view illustrating an example quad pixel with a material layer with a pyramidal structure according to some embodiments.

FIG. 24B is a schematic side view illustrating an example quad pixel with a color filter with a pyramidal structure according to some embodiments.

FIG. 24C is a schematic side view illustrating an example quad pixel with a color filter, a material layer, and a pyramidal structure according to some embodiments.

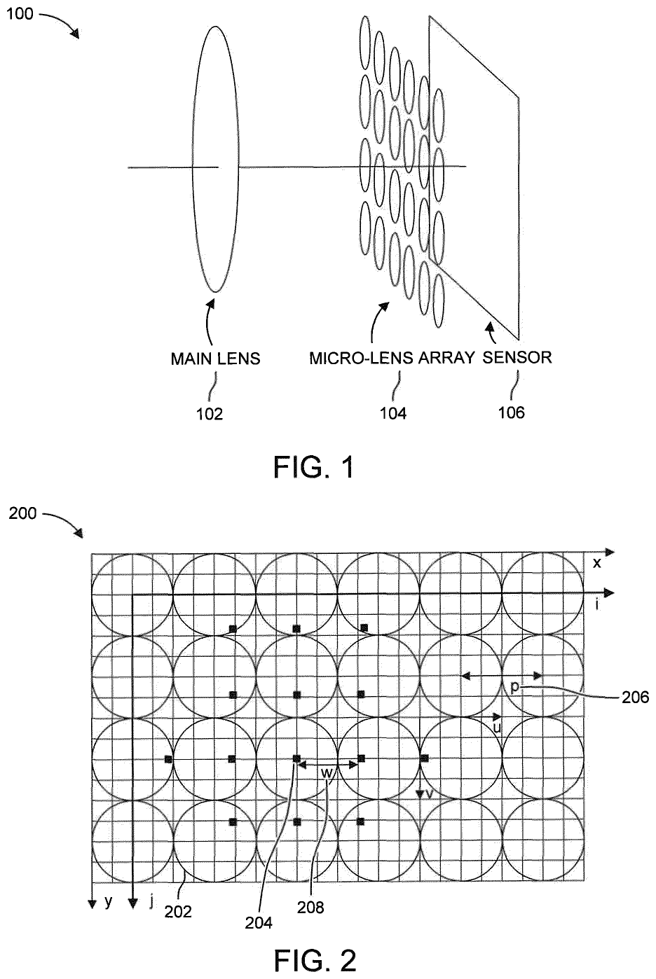

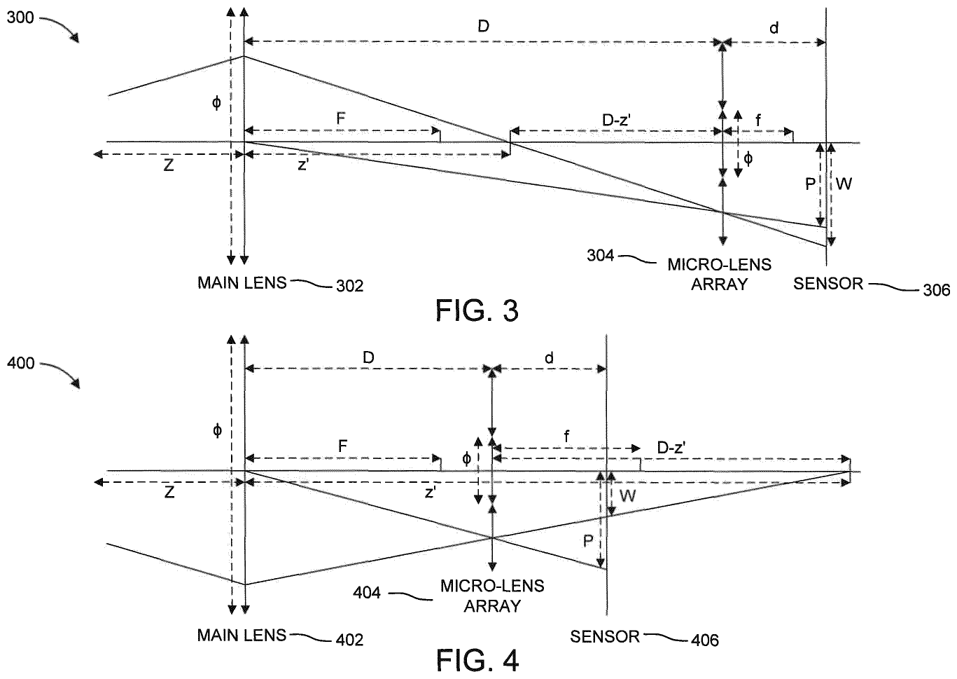

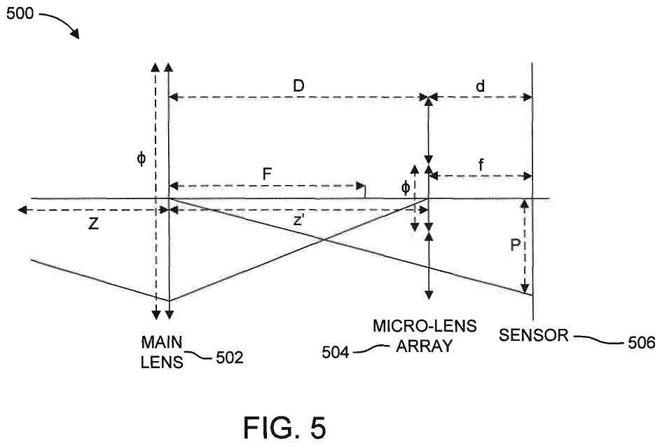

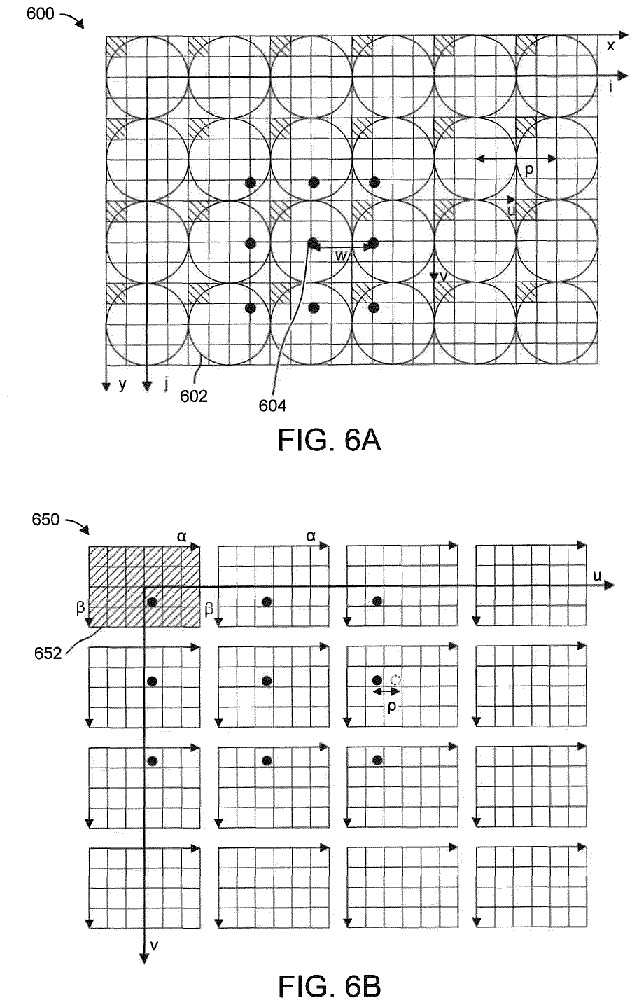

The entities, connections, arrangements, and the like that are depicted in—and described in connection with—the various figures are presented by way of example and not by way of limitation. As such, any and all statements or other indications as to what a particular figure “depicts,” what a particular element or entity in a particular figure “is” or “has,” and any and all similar statements—that may in isolation and out of context be read as absolute and therefore limiting—may only properly be read as being constructively preceded by a clause such as “In at least one embodiment, . . . ” For brevity and clarity of presentation, this implied leading clause is not repeated ad nauseum in the detailed description.

### DETAILED DESCRIPTION

A wireless transmit/receive unit (WTRU) may be used, e.g., as a plenoptic camera in some embodiments described herein.

FIG. 7 is a system diagram illustrating an example WTRU 702. As shown in FIG. 7, the WTRU 702 may include a processor 718, a transceiver 720, a transmit/receive element 722, a speaker/microphone 724, a keypad 726, a display/touchpad 728, non-removable memory 730, removable memory 732, a power source 734, a camera 736, and/or other peripherals 738, among others. It will be appreciated that the WTRU 702 may include any sub-combination of the foregoing elements while remaining consistent with an embodiment.

The processor 718 may be a general purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, and the like. The processor 718 may perform signal coding, data processing, power control, input/output processing, and/or any other functionality that enables the WTRU 702 to operate in a wireless environment. The processor 718 may be coupled to the transceiver 720, which may be coupled to the transmit/receive element 722. While FIG. 7 depicts the processor 718 and the transceiver 720 as separate components, it will be appreciated that the processor 718 and the transceiver 720 may be integrated together in an electronic package or chip.

The transmit/receive element 722 may be configured to transmit signals to, or receive signals from, a base station over the air interface 716. For example, in one embodiment, the transmit/receive element 722 may be an antenna configured to transmit and/or receive RF signals. In an embodiment, the transmit/receive element 722 may be an emitter/detector configured to transmit and/or receive IR, UV, or visible light signals, for example. In yet another embodiment, the transmit/receive element 722 may be configured to transmit and/or receive both RF and light signals. It will be appreciated that the transmit/receive element 722 may be configured to transmit and/or receive any combination of wireless signals.

The transceiver 720 may be configured to modulate the signals that are to be transmitted by the transmit/receive element 722 and to demodulate the signals that are received by the transmit/receive element 722. The WTRU 702 may have multi-mode capabilities. Thus, the transceiver 720 may include multiple transceivers for enabling the WTRU 702 to communicate via multiple radio access technologies, such as New Radio and IEEE 802.11, for example.

The processor 718 of the WTRU 702 may be coupled to, and may receive user input data from, the speaker/microphone 724, the keypad 726, the display/touchpad 728 (e.g., a liquid crystal display (LCD) display unit or organic light-emitting diode (OLED) display unit), and/or the camera 736. The processor 718 may also output user data to the speaker/microphone 724, the keypad 726, and/or the display/touchpad 728. In addition, the processor 718 may access information from, and store data in, any type of suitable memory, such as the non-removable memory 730 and/or the removable memory 732. The non-removable memory 730 may include random-access memory (RAM), read-only memory (ROM), a hard disk, or any other type of memory storage device. The removable memory 732 may include a subscriber identity module (SIM) card, a memory stick, a secure digital (SD) memory card, and the like. In other embodiments, the processor 718 may access information from, and store data in, memory that is not physically located on the WTRU 702, such as on a server or a home computer (not shown).

The processor 718 may receive power from the power source 734, and may be configured to distribute and/or control the power to the other components in the WTRU 702. The power source 734 may be any suitable device for powering the WTRU 702. For example, the power source 734 may include one or more dry cell batteries (e.g., nickel-cadmium (NiCd), nickel-zinc (NiZn), nickel metal hydride (NiMH), lithium-ion (Li-ion), etc.), solar cells, fuel cells, and the like.

The processor 718 may also be coupled to the GPS chipset 736, which may be configured to provide location information (e.g., longitude and latitude) regarding the current location of the WTRU 702. In addition to, or in lieu of, the information from the GPS chipset 736, the WTRU 702 may receive location information over the air interface 716 from a base station and/or determine its location based on the timing of the signals being received from two or more nearby base stations. It will be appreciated that the WTRU 702 may acquire location information by way of any suitable location-determination method while remaining consistent with an embodiment.

The processor 718 may further be coupled to other peripherals 738, which may include one or more software and/or hardware modules that provide additional features, functionality and/or wired or wireless connectivity. For example, the peripherals 738 may include an accelerometer, an e-compass, a satellite transceiver, additional digital camera (for photographs and/or video), a universal serial bus (USB) port, a vibration device, a television transceiver, a hands free headset, a Bluetooth© module, a frequency modulated (FM) radio unit, a digital music player, a media player, a video game player module, an Internet browser, a Virtual Reality and/or Augmented Reality (VR/AR) device, an activity tracker, and the like. The peripherals 738 may include one or more sensors, the sensors may be one or more of a gyroscope, an accelerometer, a hall effect sensor, a magnetometer, an orientation sensor, a proximity sensor, a temperature sensor, a time sensor; a geolocation sensor; an altimeter, a light sensor, a touch sensor, a magnetometer, a barometer, a gesture sensor, a biometric sensor, and/or a humidity sensor.

The emulation devices may be designed to implement one or more tests of other devices in a lab environment and/or in an operator network environment. For example, the one or more emulation devices may perform the one or more, or all, functions while being fully or partially implemented and/or deployed as part of a wired and/or wireless communication network in order to test other devices within the communication network. The one or more emulation devices may perform the one or more, or all, functions while being temporarily implemented/deployed as part of a wired and/or wireless communication network. The emulation device may be directly coupled to another device for purposes of testing and/or may performing testing using over-the-air wireless communications.

The one or more emulation devices may perform the one or more, including all, functions while not being implemented/deployed as part of a wired and/or wireless communication network. For example, the emulation devices may be utilized in a testing scenario in a testing laboratory and/or a non-deployed (e.g., testing) wired and/or wireless communication network in order to implement testing of one or more components. The one or more emulation devices may be test equipment. Direct RF coupling and/or wireless communications via RF circuitry (e.g., which may include one or more antennas) may be used by the emulation devices to transmit and/or receive data.

As noted previously, an integrated plenoptic sensor is an imaging sensor in which a microlens is shared between multiple subpixels. An integrated plenoptic sensor records a “4D light-field” which may give indications on the angle of incidence of light. An integrated plenoptic sensor may be used on cameras and smartphones to drive the autofocus of the main lens. Furthermore, an integrated plenoptic sensor may provide additional abilities, such as passive depth mapping, refocusing, or aberration correction.

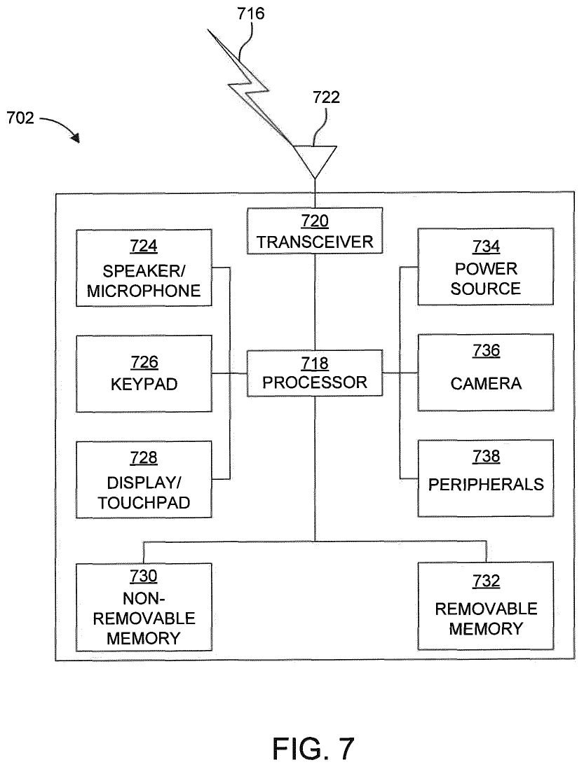

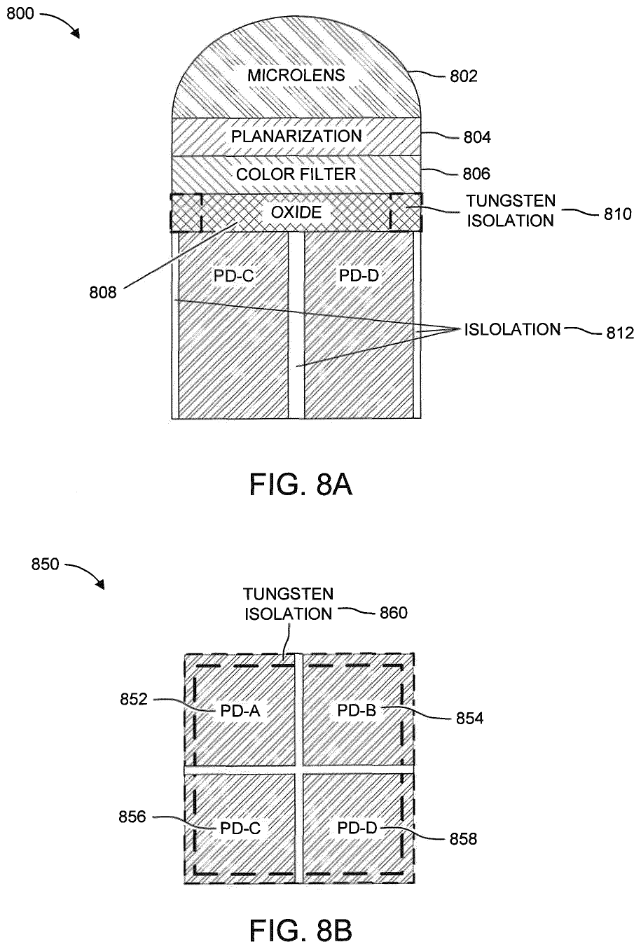

FIG. 8A is a schematic side view illustrating an example quad pixel according to some embodiments. FIG. 8B is a schematic plan view illustrating an example quad pixel according to some embodiments. For some embodiments, a quad pixel may be composed of a microlens covering a 2×2 square array of subpixels, multiple layers of different materials including a color filter, and the silicon which absorbs the light. A quad pixel may have trenches to isolate pixels and subpixels electrically and optically. According to some embodiments, a pyramid shape (not shown in FIGS. 8A and 8B) may be inside the silicon to avoid or reduce optical crosstalk between microlenses. For some embodiments, a pyramid shape may be inside the silicon to avoid or reduce optical crosstalk between pixels. FIG. 8B shows four subpixels and four photo diodes associated with each subpixel. The photo diode sensors 852, 854, 856, 858 are labeled PD-A, PD-B, PD-C, and PD-D.

In particular, an example practical implementation of the example design shown in FIG. 8A is based on a back side illuminated (BSI) pixel including a microlens 802 placed on top of planar layers with a given thickness: for example, a planarization layer 804 made of transparent resin (e.g., 500 nm), a color filter 806 (e.g., in the range of 500 nm to 1 μm), a passivation layer made of silicon dioxide 808 (e.g., 650 nm), and silicon including the four sub-pixels (4 μm) forming the 2×2 square array. For some embodiments, the planarization layer 804 may be made of the same material as the microlens 802. For some embodiments, the planarization layer 804 is made of a different resin than the microlens 802. For some embodiments, the planarization layer 804 is a transparent, under-layer that has a thickness in the range of 200 nm to 500 nm. The color filter 806 may be, for example, a red color filter, a green color filter, or a blue color filter. In some embodiments, the color filter 806 may have subpixel areas of different color. For some embodiments, the passivation layer 804 may be made of one or more layers of inorganic material, including, e.g., hafnium oxide, aluminum oxide, and/or tantalum oxide, and may be capped by silicon oxide. Collectively, these materials are known as high-k dielectric materials in the microelectronics industry and may be non-stoichiometric oxides. For example, silicon oxide may be non-stoichiometric. For some embodiments, silicon dioxide may be used instead of silicon oxide. For some embodiments, the total thickness of the planarization layer 804, the color filter 806, and the passivation layer may be within the range of slightly less than 100 nm to less than 1 μm. Of course, the materials and dimensions are merely examples. According to the example, deep trench isolation (DTI) 812 (e.g., silicon oxide or occasionally tungsten) inside silicon may be used to isolate the photodiodes from each other (e.g., 100 nm wide). For some embodiments, capacitive DTI may be used and may include deep trenches filled with, e.g., (1) a thin silicon oxide liner and/or (2) a core of polycrystalline silicon that may be biased. For some embodiments, the tungsten isolation 810 may be used at the passivation layer level to “guide” the light to the silicon (and then to prevent crosstalk from one pixel to another pixel) and/or to mask part of the pixel to protect part of the pixel from light. In addition, isolation of the color filter may be present. The isolation may be made of material with a lower refractive index than the color filter resin. The isolation may be silicon oxide or may be a dedicated resin for some embodiments. For some embodiments, the isolation may be associated with tungsten walls 860. FIG. 8A shows a view 800 from the side and FIG. 8B shows a view 850 from the top (not to scale).

Examples of quad-pixel sensors, along with example quad-pixel sensor designs and examples of related wave optics simulations and results, are included in: Chataignier, G., Vandame, B., and Vaillant, J., Joint Electromagnetic and Ray-Tracing Simulations for Quad-Pixel Sensor and Computational Imaging, 27:21 OPTICS EXPRESS (Oct. 14, 2019) (“Chataignier”).

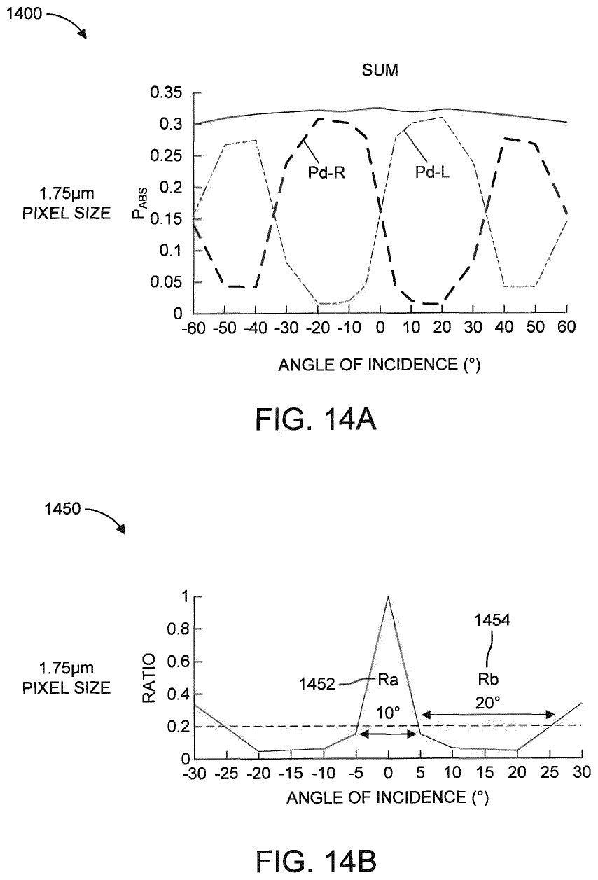

For some embodiments, a shape such as a pyramid shape (not shown in FIG. 8A or 8B) may be inside (e.g., etched inside or into) the silicon to avoid or reduce optical crosstalk between microlenses. For some embodiments, the pyramid shape and/or pyramidal structure may have one or more of (or any combination of) the following positive effects: (1) to reduce optical crosstalk between adjacent microlenses, (2) to reduce optical crosstalk between adjacent (subpixel) sensors; (3) to reduce the width of the “blind” angular zone, which is denoted as Rain FIG. 14B's graph of

$$( \frac{{P}_{{abs}_{left}}}{{P}_{{abs}_{right}}} )$$

ratio vs. angle of incidence; (4) to increase sensitivity between adjacent (subpixel) sensors; (5) to increase angular discrimination of light incident on the microlens (or main lens for some embodiments) at an angle near a chief ray angle of the microlens. For some embodiments, one or more external insulators may be adjacent to an external edge of a photo detector. For example, an external insulator (or isolator for some embodiments) be attached to or next to a portion of a photo detector, such as the example shown in FIG. 8A. For some embodiments, one or more external insulators may be adjacent to an external edge of at least one of the plenoptic subpixel sensors.

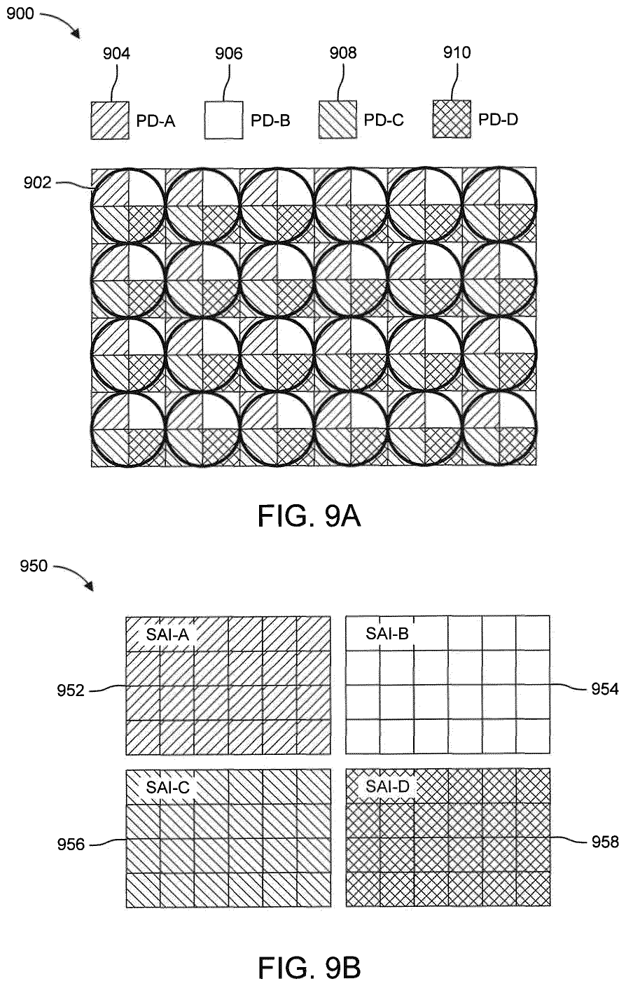

FIG. 9A is a schematic plan view illustrating an example sub aperture image (SAI) pattern for an array of quad pixels according to some embodiments. FIG. 9B is a schematic plan view illustrating example sub aperture images (SAIs) according to some embodiments.

FIG. 9A shows an array 900 of quad pixels. Each microlens produces a micro-image 902 which is schematically represented by a circle. A set 950 of Sub Aperture Images (SAIs) 952, 954, 956, 958 may be used with photo diode sensors arranged in a subpixel configuration. The SAIs are formed by each subpixel 904, 906, 908, 910 having the same position under the array of microlenses. Depending on the focus distance, the distance to an object, and the geometrical aberrations of the main lens, the object may appear shifted between the SAIs. The amount of translation, or disparity, is at the base of certain algorithms. The SAIs may be shifted (for some embodiments globally) to refocus or locally correct the main lens' aberrations. The final image is the summation of the shifted SAIs.

A quad-pixel was simulated using electromagnetic simulations with Finite Difference Time Domain (FDTD) to study and optimize the design of quad pixels of 1.75 μm and 0.8 μm in size. The power absorbed by the silicon (P_{abs}) as a function of the angle of incidence is called the angular response of the pixel. Two types of crosstalk have been identified: inside the microlens and between the microlenses. In the manner of Kobayashi, Masahiro, A Low Noise and High Sensitivity Image Sensor with Imaging and Phase-Difference Detection AF in All Pixels, 4:2 ITE TRANS. ON MEDIA TECHN. AND APPLICATIONS (MTA) 123-128 (2016) (“Kobayashi”), a specific figure of merit was determined and used to compare different quad pixel designs. These comparisons are described later in this specification.

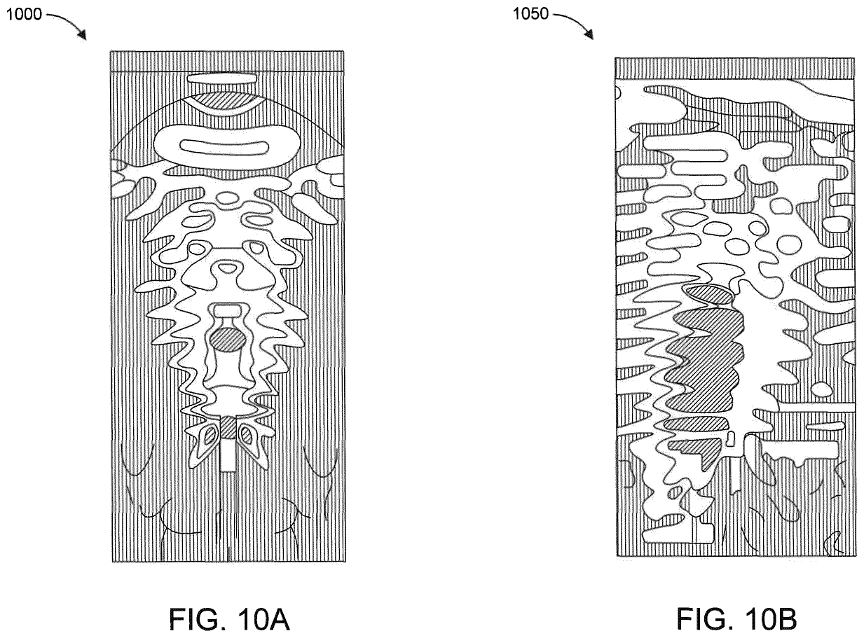

FIG. 10A is a schematic side view illustrating an example diffraction pattern inside a pixel for light entering at normal incidence according to some embodiments. FIG. 10B is a schematic side view illustrating an example diffraction pattern inside a pixel for light entering at an off-angle according to some embodiments.

When light enters the microlens, the light forms a diffraction spot, which has a spatial extent. The diffraction spot may cause crosstalk between subpixels, especially near normal incidence (perpendicular to the surface). FIG. 10A shows a diffraction pattern 1000 for light entering the curved microlens at the top of the figure and forming a diffraction spot at the surface of the silicon. The diffraction spot has a spatial extent (or width) that causes optical crosstalk between two subpixel sensors. FIG. 10B shows a diffraction pattern 1050 for light entering the curved microlens at an off-angle to the top of the figure and forming a diffraction spot mostly located above the left subpixel sensor and having less crosstalk than FIG. 10A.

For light entering a microlens at small angles of incidence, diffraction inside the pixel may be a source of crosstalk between the subpixels. Reducing crosstalk between subpixels may help avoid pollution between SAIs. With more crosstalk, the SAIs look more similar. If the SAIs look more similar, disparity estimation is more difficult because there are less clues indicating depth.

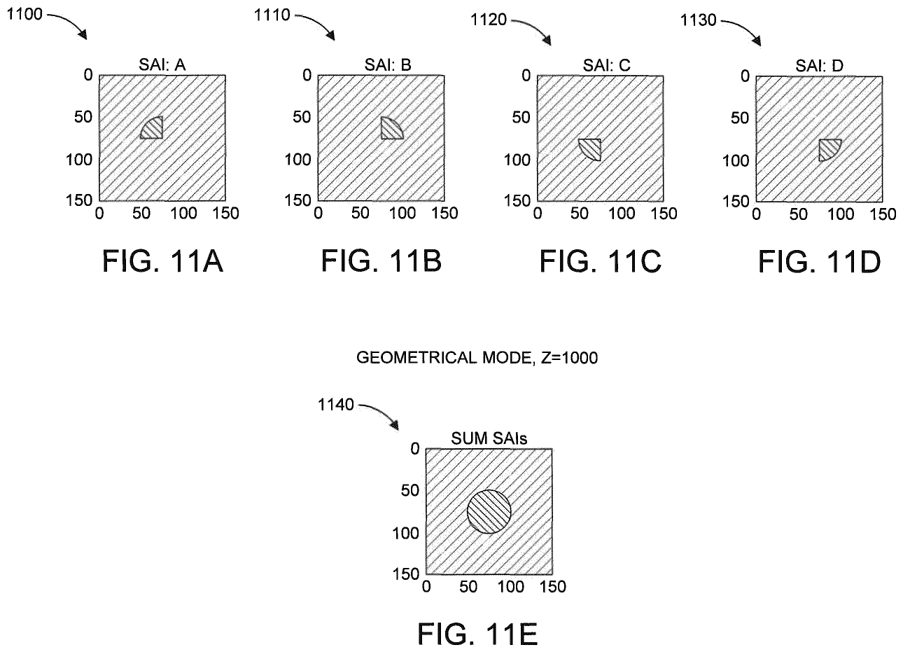

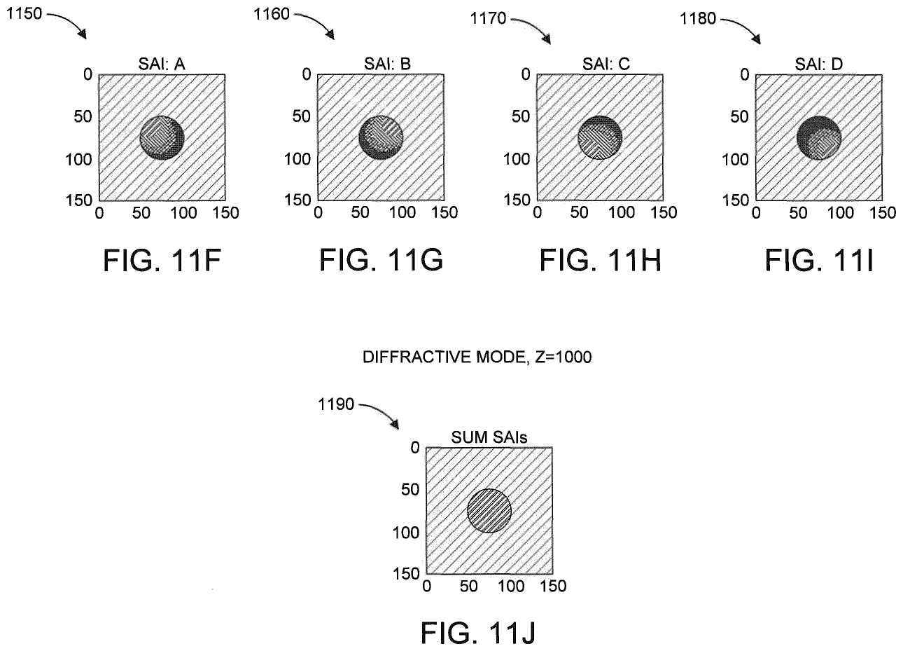

FIGS. 11A to 11D are schematic plan views illustrating example sub aperture images A to D for an out-of-focus white spot without diffraction according to some embodiments. FIG. 11E is a schematic plan view illustrating an example summation of sub aperture images A to D in FIGS. 11A to 11D according to some embodiments. FIGS. 11F to 111 are schematic plan views illustrating example sub aperture images A to D for an out-of-focus white spot with diffraction according to some embodiments. FIG. 11J is a schematic plan view illustrating an example summation of sub aperture images A to D in FIGS. 11F to 111 according to some embodiments.

Compare the sub aperture images 1100, 1110, 1120, 1130, 1140 of FIGS. 11A to 11E with the sub aperture images 1150, 1160, 1170, 1180, 1190 of FIGS. 11F to 11J. Both sets of figures show the same out-of-focus point, but the diffraction in FIGS. 11F to 11J causes crosstalk. The crosstalk induces a blur function shown in each of the sub aperture images (SAIs) of FIGS. 11F to 111. The blur function prevents an accurate disparity estimation. The amount of crosstalk may depend on the size of the microlens in which larger microlenses have more crosstalk, and crosstalk may be difficult to avoid.

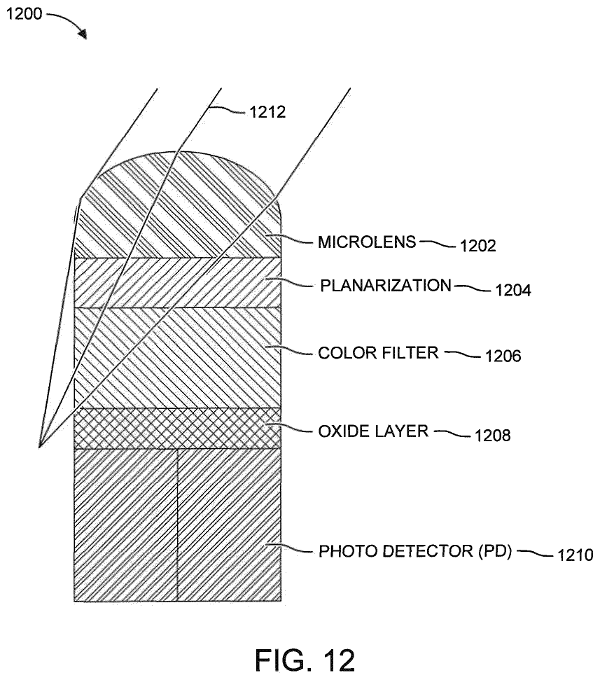

FIG. 12 is a schematic side view illustrating an example crosstalk between microlenses according to some embodiments. Crosstalk between microlenses happens when the angle of incidence of light is too high. There are two main reasons: the aperture of the main lens is too big, or the chief ray angle is too high or not well corrected (or a mix of both). Crosstalk between microlenses at a high angle of incidence degrades the final image, and reduction or avoidance of such crosstalk is desirable.

In FIG. 12, the angle of incidence is larger and off-angle. As a result, the chief ray angle of the chief ray 1212 is too high, and the light rays pass through the microlens and towards a neighboring pixel due to crosstalk instead of going towards the center of the pixel while passing through the planarization layer 1204, color filter 1206, oxide layer 1208, and photo detector 1210.

Described herein are embodiments which may decrease crosstalk between microlenses 1202. With a reduction in crosstalk, some embodiments may pair a sensor with a main lens that has a higher f-number (f/#). The f-number is a ratio of the focal length to the diameter of the lens. The higher the f-number, the smaller the lens. Some embodiments may make the sensor more resilient with respect to the chief ray angle.

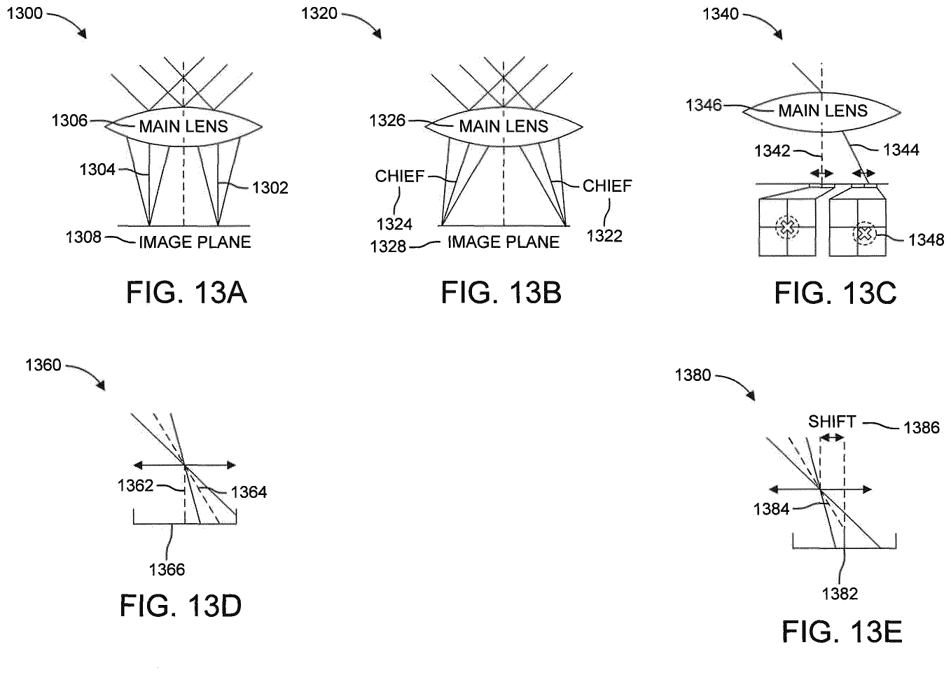

FIGS. 13A-13E are schematic plan views illustrating an example Chief Ray Angle correction via a microlens shift according to some embodiments. For purposes of this description, a Chief Ray (CR) may be defined as a light ray that passes through the center of a main lens. FIG. 13A shows a pixel structure 1300 for a telecentric lens in which the Chief Rays 1302, 1304 are perpendicular to the image plane 1308. If the main lens 1306, 1326 is not telecentric in the image space, the chief ray 1322, 1324 forms an angle, the Chief Ray Angle (CRA), with the sensor and image plane 1328 as shown in the pixel structure 1320 of FIG. 13B.

FIG. 13C shows a pixel structure 1340 for a first pixel sensor aligned with a first chief ray 1342 passing through the center of the main lens 1346 along the optical axis of the main lens. A second chief ray 1344 passes through the main lens 1346 and hits a second pixel sensor off-center 1348. FIG. 13D shows a pixel structure 1360 for an enlarged view of the chief ray 1362, the second chief ray 1364, and the second pixel sensor 1366. Such a situation may be corrected to avoid crosstalk between pixel sensors. Furthermore, such a situation may be corrected so that a centered angular response exists for each pixel, independent of the position of the sensor. For some embodiments, one way to correct the Chief Ray Angle (CRA) is to decenter (or shift) the microlens. The amount of translation may be calculated given the specifications for the main lens. FIG. 13E shows a pixel structure 1380 for a Chief Ray Angle correction 1386 in which the microlens is shifted. As a result, the chief ray 1364 shown in FIG. 13D is shifted to hit the center 1382 of the pixel sensor for the chief ray 1384 shown in FIG. 13E. For some embodiments, the main lens characteristic of CRA vs. image height gives the chief ray angle as a function of position in the image plane. Hence, for each pixel, the location of the pixel within the image plane is used to determine the CRA seen by the pixel and to determine the amount of shift of the microlens for that particular pixel.

For some embodiments, the microlens may be configured to shift a chief ray angle corresponding to a pixel offset of two pixels. For example, the microlens may have a shape or arc that shifts the chief ray angle by an amount corresponding to a shift as shown in FIG. 13E. For some embodiments, a pixel (or a picture element for some embodiments) corresponds to a microlens that is an optical element that spatially samples an image. Sub-pixels may denote a matrix of elements below the microlens. The microlens shift may correspond to, e.g., the center of the pixel (or the center of the group of sub-pixels) at the silicon level. For example, the matrix of sub-pixels may include quad-pixels, 2×2-pixels, 3×3-pixels, and other arrangements for a matrix of pixels.

FIG. 14A is a graph illustrating example left and right photo detect (PD) signals (P_{abs}_{_{left}}, P_{abs}_{_{right}}) vs. angle of incidence according to some embodiments. For the graph 1400 in FIG. 14A, the left photo detect signal is PD-L 1402, and the right photo detect signal is PD-R 1404.

For each simulated angle of incidence, the left/right ratio described in Kobayashi was used to compare different pixel designs. This figure of merit, the

$$( \frac{{P}_{{abs}_{left}}}{{P}_{{abs}_{right}}} )$$

ratio, was computed and compared to an arbitrary threshold. If the ratio was below the threshold, the signal was treated as “good.” Three areas on the ratio curve were distinguished:
a) At low angles of incidence in which the ratio is above the threshold, the signal is considered “bad” due to microlens diffraction, as discussed above. The range of this area is denoted Rₐ.
b) For angles of incidence in which the ratio is below the threshold, the signal is considered “good.” The range of this area is denoted R_{b}
c) For angles of incidence in which the ratio goes above the threshold again (angles of incidence beyond the end of R_{b}), the signal is considered “bad” due to crosstalk between microlenses, as discussed above.

FIG. 14B is a graph illustrating an example ratio of left and right PD signals

$$( \frac{{P}_{{abs}_{left}}}{{P}_{{abs}_{right}}} )$$

vs. angle of incidence according to some embodiments. The graph 1450 in FIG. 14B indicates the first range (item a 1452) for angles of incidence of −5° to +5°. The second range (item b 1454) is shown for angles of incidence of 5° to 25°. The third range (item c) in FIG. 14B includes angle of incidence above 25°. For the example shown in FIG. 14B, Rₐ is 10° and R_{b} is 20°.

For some embodiments, the angular range Rₐ is reduced (or even minimized for some embodiments), and the angular range R_{b} is increased (of even maximized for some embodiments). For some embodiments, the radius of curvature of the microlens and the height of the optical stack (the distance between the bottom of the microlens and the surface of the silicon) are adjusted to reduce Rₐ and increase R_{b}.

To speed up simulation of a quad-pixel, only subpixels A and B, which are shown in FIG. 8B, were simulated. The real “left signal” (P_{abs}_{_{left}}) is the sum of the subpixels A and C. The real “right signal” (P_{abs}_{_{right}}) is the sum of subpixels B and D. Because of the symmetry of a quad pixel along the horizontal and vertical axes, the ratio calculated above was not affected. Although the left/right ratio was used above, the top/bottom ratio could have been used instead because of the symmetry of the quad-pixel.

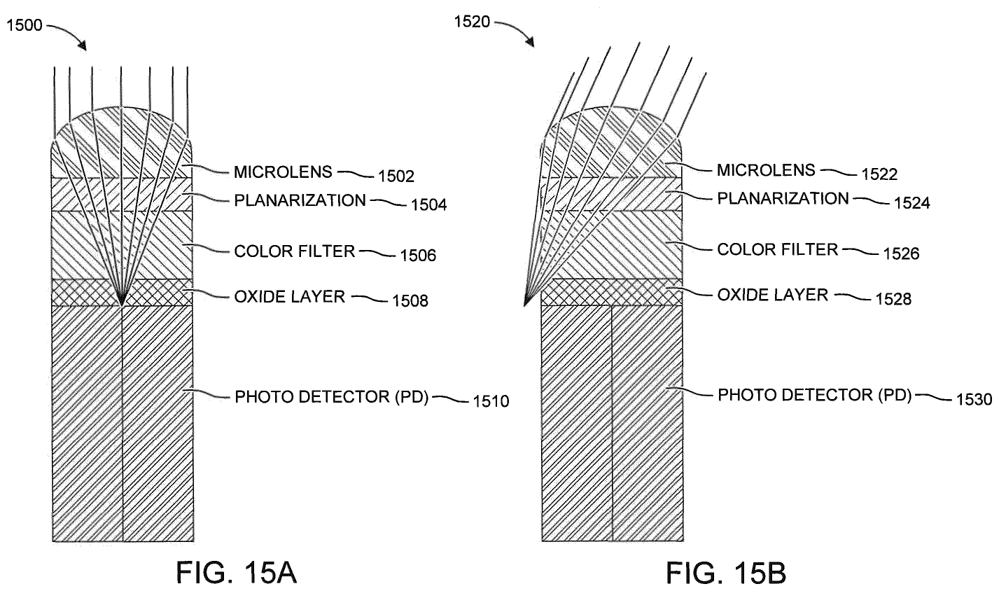

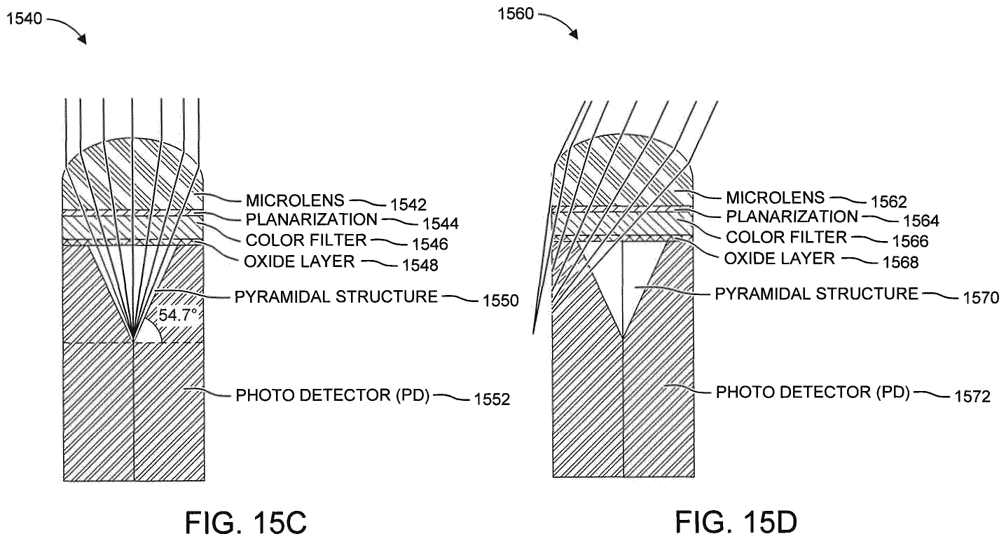

FIG. 15A is a schematic side view illustrating an example low angle of incidence for a quad pixel without a pyramid shape etched in the silicon according to some embodiments. FIG. 15B is a schematic side view illustrating an example higher angle of incidence for a quad pixel without a pyramid shape etched in the silicon according to some embodiments. FIG. 15C is a schematic side view illustrating an example low angle of incidence for a quad pixel with a pyramid shape etched in the silicon according to some embodiments. FIG. 15D is a schematic side view illustrating an example higher angle of incidence for a quad pixel with a pyramid shape etched in the silicon according to some embodiments.

For some embodiments, an inverted pyramid shape is etched in the silicon to reduce crosstalk between microlenses. The use of such an inverted pyramid shape (which may be a pyramidal structure or pyramid-shaped prism depending on context for some embodiments) may increase convergence (and even ensure optimal convergence for some embodiments) of the microlens at low angles of incidence, thereby reducing Rₐ, and decrease (or “break”) convergence at higher angles of incidence. As such, at higher angles of incidence, the silicon absorbs more of the light before the light enters a neighboring pixel cell structure.

For some embodiments, the optical stack may be decreased (or “thinned”). For example, compare the optical stack 1500, 1520 of microlens 1502, 1522, planarization 1504, 1524, color filter 1506, 1526, oxide layer 1508, 1528, and photo detector 1510, 1530 of FIGS. 15A and 15B with the optical stack 1540, 1560 of microlens 1542, 1562, planarization 1544, 1564, color filter 1546, 1566, oxide layer 1548, 1568, pyramidal structure 1550, 1570, and photo detector 1552, 1572 of FIGS. 15C and 15D. The optical stack, for some embodiments, may be thinned by an amount equal to as much as the height of the inverted pyramid shape. For some embodiments, the stack (the distance between microlens and an upper face of the silicon) may be thinner by having part of the material (such as mostly the color filters) filling the pyramidal structure. Generally, the silicon has a very high refractive index (n=3.8 to 4.0 over the visible and near-infrared range). Placing oxide, resin, and/or other transparent materials (which have a refractive index of n=1.4 to 2.2 over the same spectral range as the silicon) above the optical prism will deviate the light. For some embodiments, the horizontal facet angle may be set to 54.7°, which may be due to a manufacturing process. For example, in embodiments using a wet etching process with silicon, such an angle may be used since 54.7° is a natural angle formed by the silicon when the silicon is etched due to the crystalline structure of the silicon. The angle may vary with the use of other processes and/or materials. FIGS. 15A and 15B show a quad pixel without a pyramidal structure 1500, 1520. FIGS. 15C and 15D show a quad pixel adjusted using a pyramidal structure 1540, 1560. For some embodiments, the pyramidal structure 1550, 1570 may be generated with a photoresist process using grayscale lithography, for example, and the pyramid shape of the pyramidal structure may be transferred into the silicon using a dry etching process. For some embodiments, the horizontal facet angle may be an angle other than 54.7° and may be tuned depending on the configuration of the pixel, the objective of the pyramidal structure, and requirements for the width of Ra and Rb.

For some embodiments, a pixel stack structure may include, e.g., a microlens, a color filter system (for example), and two or more plenoptic subpixel sensors, in which the two or more plenoptic subpixel sensors may include two or more photodiodes formed in a silicon layer, and in which a pyramid shape is etched in the two or more respective silicon photodiodes formed in the silicon layer. For some embodiments, the pyramid shape and/or pyramidal structure may be configured to reduce optical crosstalk between at least two of the two or more plenoptic subpixel sensors. In some embodiments, the pyramidal structure may include a pyramid shaped insulator or pyramid shaped insulator structure. For some embodiments, a horizontal facet angle of the pyramid shape of the pyramidal structure may be 54.7 degrees. An example of a pyramidal structure 1550 is shown in FIG. 15C. For some embodiments, the color filter system may include a planarization layer and a color filter layer.

An example color filter system is shown in FIG. 15C for some embodiments. For some embodiments, one or more plenoptic subpixel sensors may be adjacent to the color filter system. For some embodiments, the pixel stack structure may include an oxide layer, in which the oxide layer is adjacent to the color filter system, in which at least one of the plenoptic subpixel sensors may be adjacent to the oxide layer, and in which the oxide layer may be between the color filter system and at least one of the plenoptic subpixel sensors. For some embodiments, a base of the pyramid portion of the pyramid shape may be adjacent to the oxide layer. For some embodiments, the size of a base of the pyramid portion of the pyramid shape may be adjusted based on a curvature of the microlens. For example, the size of the base of the pyramid may be adjusted to be slightly wider than the area over which low angle, near incident light rays strike the pyramidal structure after passing through the microlens and one or more other layers, such as the planarization, color filter, and oxide layers. FIG. 15C shows one example embodiment of such a pyramidal structure. For some embodiments, the pyramid shape may be symmetrical along a first plane cutting through a center of the pyramid shape and symmetrical along a second plane cutting through the center of the pyramid shape, in which the first plane is perpendicular to the second plane. For example, the two planes may form a “plus” type shape if viewed via a top of the pixel stack structure for some embodiments. For some embodiments, the color filter system may be adjacent to the microlens. For example, the planarization layer may be part of the colorfilter layer or may not be present for some embodiments. For some embodiments, the base of the pyramidal shape, as seen from the top, may be rotated 45°. For some embodiments, the base of the pyramid shape may be a disk. For some embodiments, the tip of the pyramid shape may be a disk.

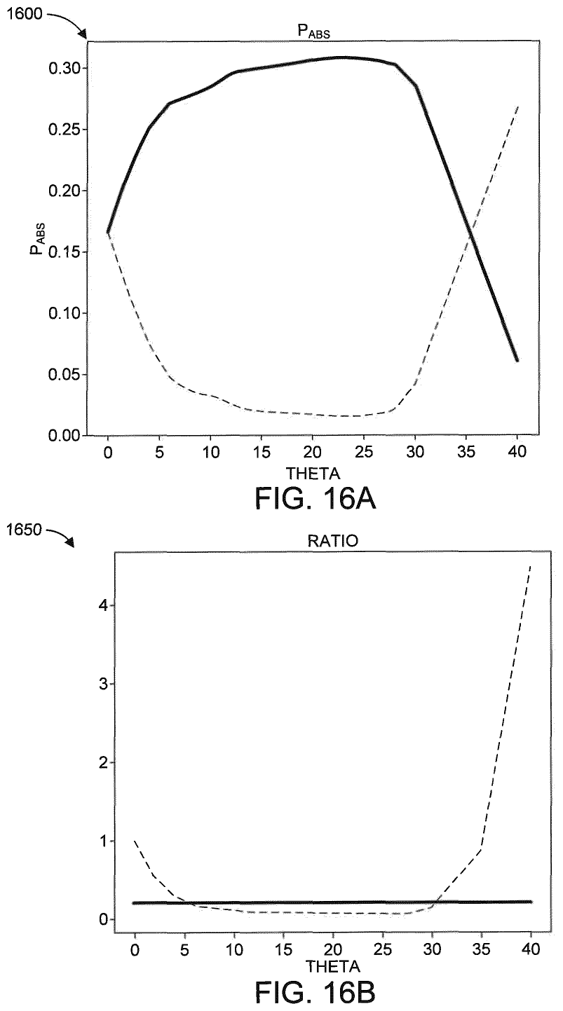

As shown in FIGS. 16A to 19B and discussed below, the pyramidal shape is able to increase the width of the Rb region. By tuning the microlens focal length and the distance between the microlens and the silicon, the width of the Ra region also may be reduced. The microlens focal length and the distance between the microlens and the silicon may be tuned together and validated by simulation. The effect of the pyramid shape is to deviate light away from the center of the pixel (corresponding to the microlens), thereby improving the right/left discrimination. This effect allows the distance between the microlens and the silicon to be reduced, enlarging the Rb region, thanks to the deep trench isolation (DTI) structure, which confines the light inside a given sub-pixel.

For some embodiments, an apparatus may include: a microlens; and two or more plenoptic subpixel sensors, the two or more plenoptic subpixel sensors including two or more photodiodes formed in a silicon layer, in which a pyramidal structure is etched in the two or more respective silicon photodiodes formed in the silicon layer. For some embodiments, the pyramid structure may be formed and/or configured for one or more of the following features: to generate an optical prism deviating light away from a center of the two or more plenoptic subpixel sensors; to reduce optical crosstalk between at least two of the two or more plenoptic subpixel sensors; to increase sensitivity of at least one of the two or more plenoptic subpixel sensors; to increase angular discrimination for light incident on the microlens at an angle near a chief ray angle of the microlens; to confine light to one of the two or more plenoptic subpixel sensors; and to reflect light away from at least one of the two or more plenoptic subpixel sensors. For some embodiments, the silicon layer may be etched with a trench conforming to a deep trench isolation (DTI) structure. For some embodiments, the focal length of the microlens may be less than a threshold.

FIG. 16A is a graph illustrating example left and right photo detect (PD) signals (P_{abs}_{_{left}}, P_{abs}_{_{right}}) vs. angle of incidence for a 3.5 μm quad pixel without a pyramid shape etched in the silicon according to some embodiments. FIG. 16B is a graph illustrating an example ratio of left and right PD signals

$$( \frac{{P}_{{abs}_{left}}}{{P}_{{abs}_{right}}} )$$

and a threshold vs. angle of incidence for a 3.5 μm quad pixel without a pyramid shape etched in the silicon according to some embodiments. The graphs 1600, 1650 of FIGS. 16A and 16B relate to a 3.5 μm quad pixel (1.75 μm subpixels) without a pyramid shape in which Rₐ is 10° and R_{b} is 25°. FIGS. 15A and 15B show a quad pixel without a pyramid shape. For FIGS. 16A and 16B, the reference design has an optical stack height of 1.9 μm (the distance between the bottom of the microlens and the top of the silicon).

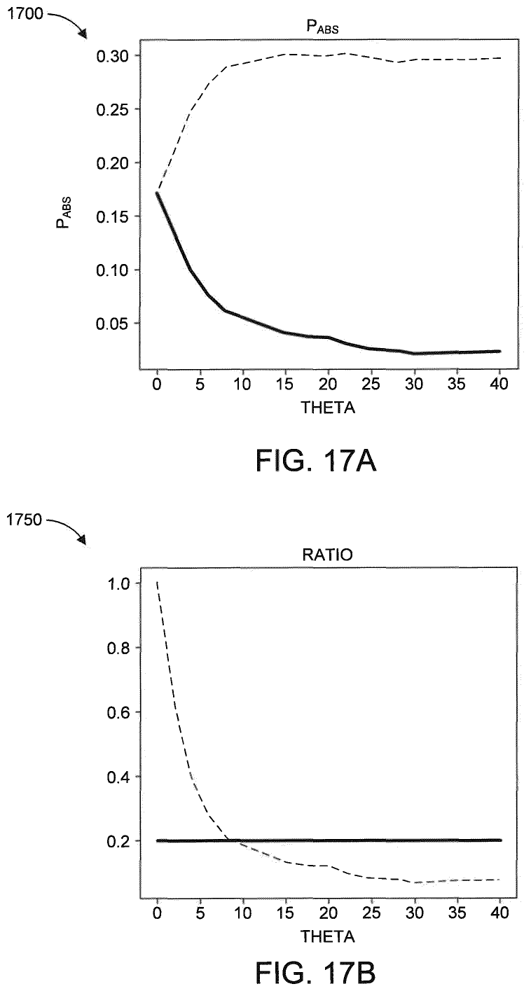

FIG. 17A is a graph illustrating example left and right photo detect (PD) signals (P_{abs}_{_{left}}, P_{abs}_{_{right}}) vs. angle of incidence for a 3.5 μm quad pixel with a pyramid shape etched in the silicon according to some embodiments. FIG. 17B is a graph illustrating an example ratio of left and right PD signals

$$( \frac{{P}_{{abs}_{left}}}{{P}_{{abs}_{right}}} )$$

and a threshold vs. angle of incidence for a 3.5 μm quad pixel with a pyramid shape etched in the silicon according to some embodiments. The graphs 1700, 1750 of FIGS. 17A and 17B relate to a 3.5 μm quad pixel (1.75 μm subpixels) with a pyramid shape in which Rₐ is 14° and R_{b} is out of range (at least 35°). For FIGS. 17A and 17B, the pyramid design has a stack height of 0.8 μm and a pyramid height of 1.236 μm.

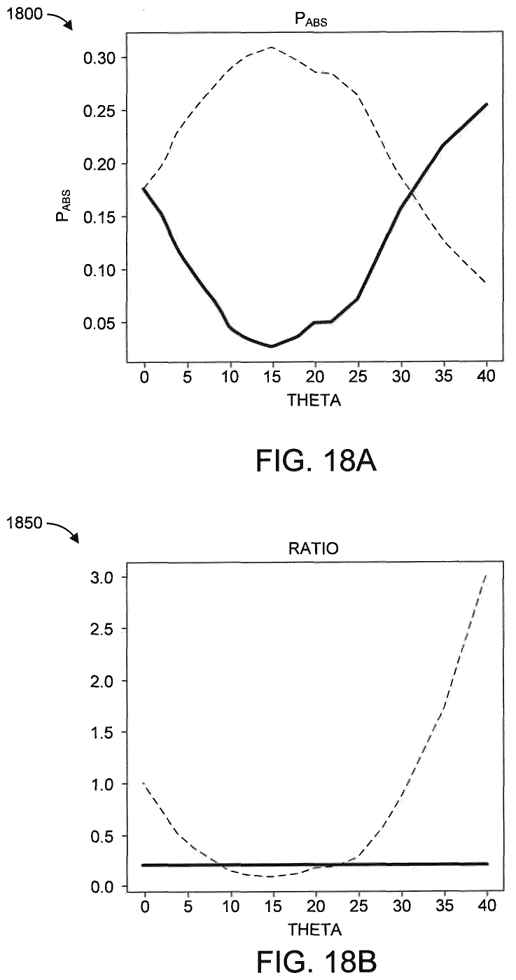

FIG. 18A is a graph illustrating example left and right photo detect (PD) signals (P_{abs}_{_{left}}, P_{abs}_{_{right}}) vs. angle of incidence for a 1.6 μm quad pixel without a pyramid shape etched in the silicon according to some embodiments. FIG. 18B is a graph illustrating an example ratio of left and right PD signals

$$( \frac{{P}_{{abs}_{left}}}{{P}_{{abs}_{rig}}} )$$

and a threshold vs. angle of incidence for a 1.6 μm quad pixel without a pyramid shape etched in the silicon according to some embodiments. The graphs 1800, 1850 of FIGS. 18A and 18B relate to a 1.6 μm quad pixel (0.8 μm subpixels) without a pyramid shape in which Rₐ is 18° and R_{b} is 14°. The quad pixel in FIGS. 12A and 12B is “normally optimized” without using a pyramid shape. For FIGS. 18A and 18B, the reference design has an optical stack height of 1.1 μm.

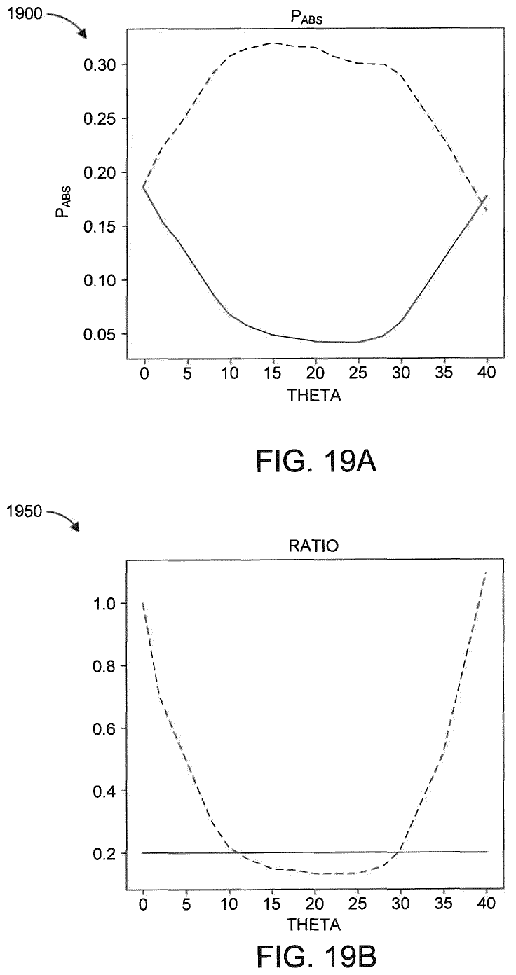

FIG. 19A is a graph illustrating example left and right photo detect (PD) signals (P_{abs}_{_{left}}, P_{abs}_{_{right}}) vs. angle of incidence for a 1.6 μm quad pixel with a pyramid shape etched in the silicon according to some embodiments. FIG. 19B is a graph illustrating an example ratio of left and right PD signals

$$( \frac{{P}_{{abs}_{left}}}{{P}_{{abs}_{right}}} )$$

and a threshold vs. angle of incidence for a 1.6 μm quad pixel with a pyramid shape etched in the silicon according to some embodiments. The graphs 1900,1950 of FIGS. 19A and 19B relate to a 1.6 μm quad pixel (0.8 μm subpixels) with a pyramid shape in which Rₐ is 20° and R_{b} is 20°. For FIGS. 19A and 19B, the pyramid design has a stack height of 0.7 μm and a pyramid height of 0.565 μm.

The threshold line in FIGS. 16B, 17B, 18B, and 19B is a ratio equal to 0.2. In FIG. 14B, the ratio is two-sided in which the angle of incidence is both positive and negative. In FIGS. 16B, 17B, 18B, and 19B, the ratio is one-sided in which the angle of incidence is only positive. The angular range Rₐ in FIGS. 16B, 17B, 18B, and 19B is doubled when using the definition for angular range Rₐ as in FIG. 14B due to this one-sided vs. two-sided ratio.

In some embodiments, using a structure with a pyramidal or pyramid shape allows good gains on the crosstalk between microlenses, and reduced (or even minimal) losses on the crosstalk between subpixels. In some embodiments, this pyramidal structure allows the use of a wide aperture main lens, and this structure makes the sensor more robust versus the Chief Ray Angle.

Constraints in the manufacturing process may limit the degree to which the optical stack components may be thinned, thereby explaining the losses on the Rₐ range. To preserve color filtering functionality, for some embodiments a limit may be imposed on the amount of height reduction of the color filter. For some embodiments, the base of the pyramid may set equal to half of the diameter of the microlens, and the height of pyramid may be set according to equation 13:

$$pyramid height = \frac{0.5 * ( micorlens diameter )}{tan ( 54.7 ° )} = 0.3 \; 54 * ( micorlens diameter ) \qquad Eq . 13$$

For some embodiments, the 54.7° facet angle may be used to determine height of the pyramid. For some embodiments, the horizontal facet angle may be an angle other than 54.7°, and the pyramid height may be calculated as shown in Eq. 14:

$$pyramid height = \frac{0.5 * ( micorlens diameter )}{tan ( horixontal facet angle )} \qquad Eq . 14$$

For some embodiments, a base of the pyramid shape may be equal to half of a diameter of the microlens. For example, the size of the base may be calculated using Eq. 13 for some embodiments.

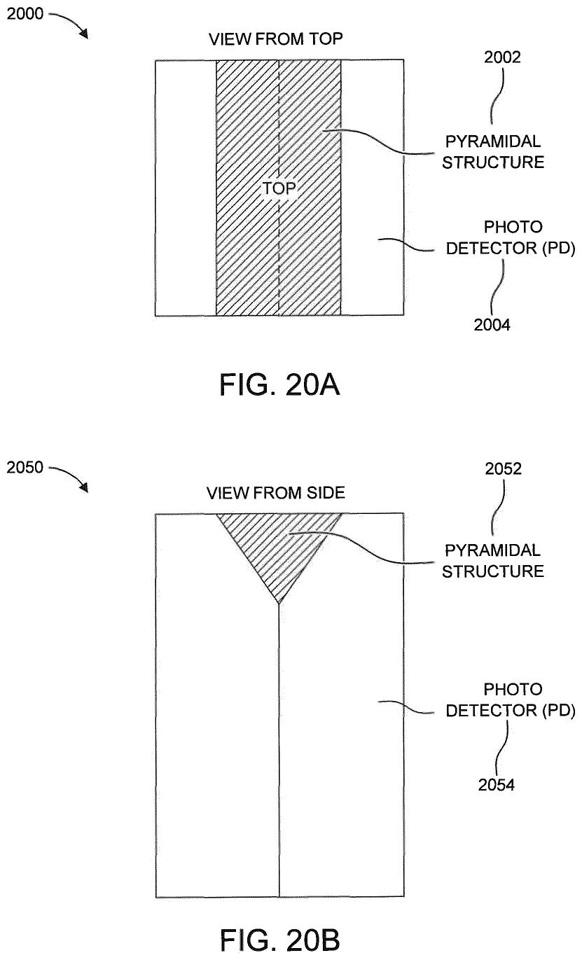

FIG. 20A is a schematic plan view illustrating an example pyramid (e.g., an inverted pyramid) for a dual pixel sensor configuration according to some embodiments. FIG. 20B is a schematic side view illustrating an example pyramid for a dual pixel sensor configuration according to some embodiments. For some embodiments, a pyramidal structure 2002, 2052, which may include a pyramid shaped insulator or other material or combination of materials, may be used with a dual pixel plenoptic sensor, such as a 2×1 grid of rectangular subpixels 2004, 2054, in which a pyramid shape is extended in one direction to create a triangular trench (e.g., a triangular prism shaped trench). FIGS. 20A and 20B show an example of how such pyramid shape may be configured with a dual pixel sensor for some embodiments.

For some embodiments, the pyramidal structure may conform to pyramid-shaped trenches etched in the silicon layer. For example, the pyramidal structure may fill in, e.g., a pyramid shaped trench such as the triangle shaped trench and form a flat base even with the top of two or more photo detectors as shown in FIG. 20B for some embodiments. For some embodiments, the plenoptic subpixel sensors may be arranged in a 2×1 grid in which the pyramid shape is centered on a line dividing the 2×1 grid in half. For example, the arrangement may be as shown in FIG. 20A in which the pyramid shape is symmetrical along the dashed line for some embodiments. For some embodiments, the pyramid portion of the pyramid shape is a triangle extruded in at least one direction. For example, a triangle may be extruded along the dashed line as shown in FIGS. 20A and 20B for some embodiments.

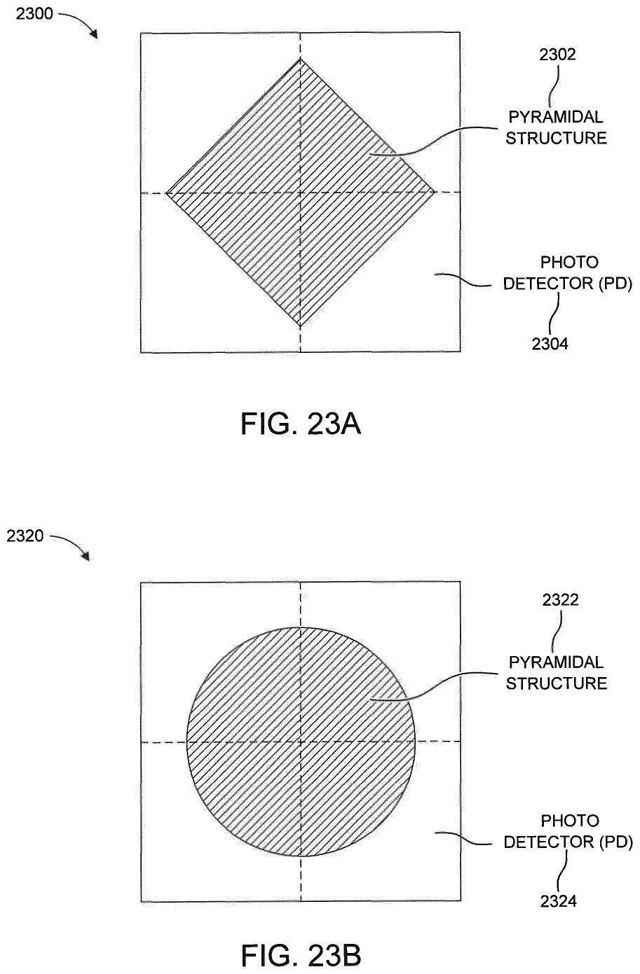

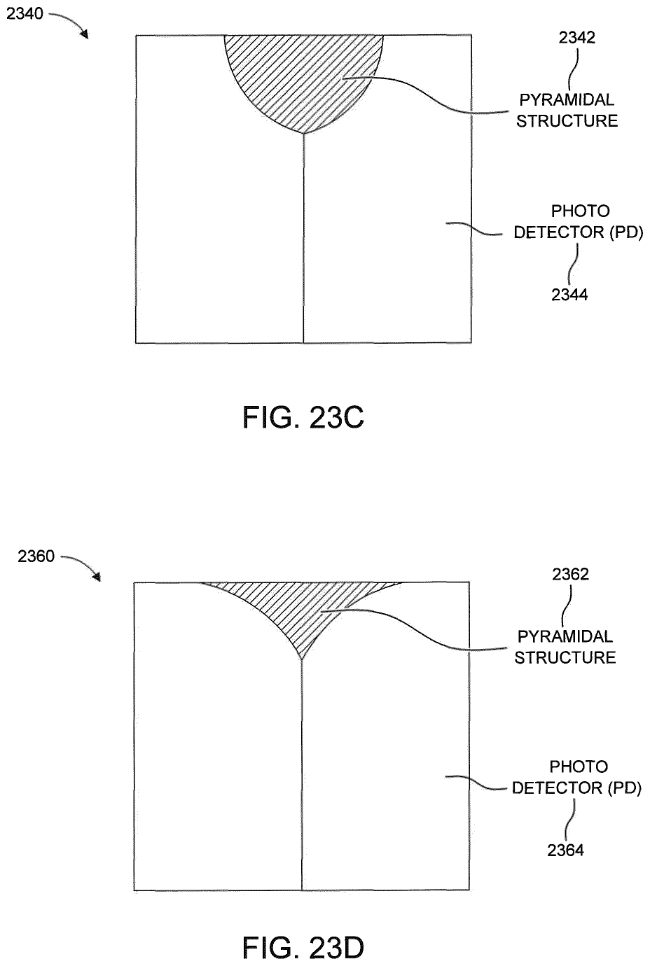

It will be understood, of course, in some embodiments and in different manufacturing processes in some embodiments, that a pyramidal structure as part of a dual or multi-pixel sensor configuration may approximate, or exhibit generally, a pyramid shape in observable, or potentially measurable, respects, but the pyramidal structure might not be formed as a “perfect” pyramid, pyramidal, or triangular abstract or geometric shape. The pyramidal structure may also have, e.g., convex or concave features, examples of which are shown in FIGS. 23C and 23D (discussed below).

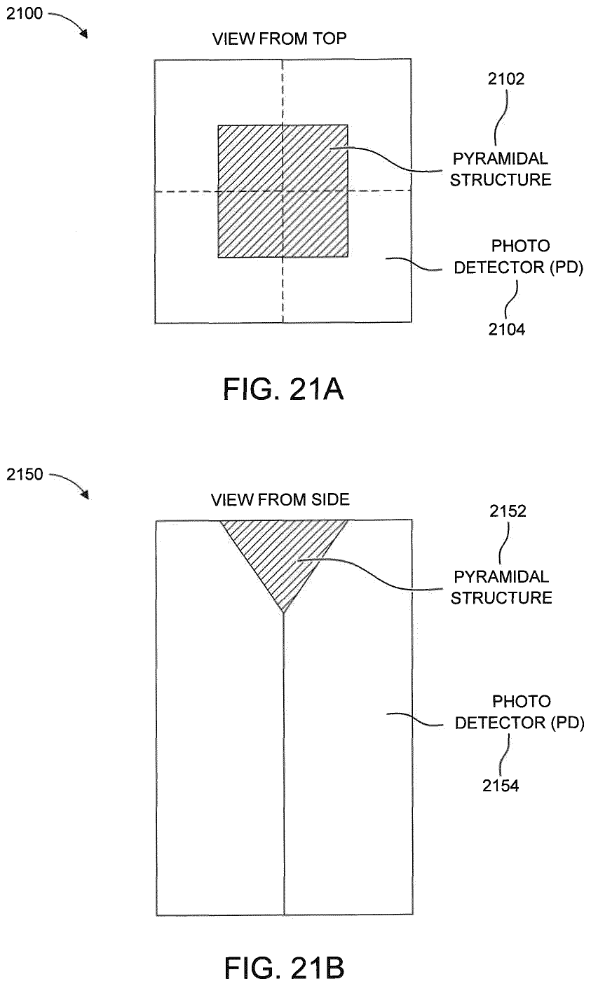

FIG. 21A is a schematic plan view illustrating an example pyramid (e.g., an inverted pyramid) for a quad pixel sensor configuration according to some embodiments. FIG. 21B is a schematic side view illustrating an example pyramid for a quad pixel sensor configuration according to some embodiments. For some embodiments, a pyramid shape 2102, 2152 may be used with a quad pixel plenoptic sensor, such as a 2×2 grid of rectangular subpixels 2104, 2154, in which a pyramid shape is used. FIGS. 21A and 21B show an example of how such a pyramid shape may be configured with a quad pixel sensor for some embodiments.

For some embodiments, the plenoptic subpixel sensors may be arranged in a 2×2 grid, in which the pyramidal shape is centered on a center of the 2×2 grid. For example, the pyramid shape may have a square base which is centered around the center point of the 2×2 grid as shown in FIG. 21A for some embodiments. In some embodiments, the pyramid shape may be rotated 45 degrees from what is shown in FIG. 21A so that the base of the pyramid is a diamond with the four corners of the square aligning with the dashed lines shown in FIG. 21A for some embodiments. For some embodiments, the plenoptic subpixel sensors may be arranged in a grid array in which the pyramid shape is centered on a center of the grid array. For some embodiments, the base of the pyramid portion of the pyramid shape may be a square. For some embodiments, in which a color filter system is included, two or more plenoptic subpixel sensors may be adjacent to the color filter system. For example, the color filter system may include a color filter layer that is directly adjacent to the top of one or more (or portions thereof) photo detectors for some embodiments. For some embodiments, the color filter system may include a filter pattern of two or more subpixels.

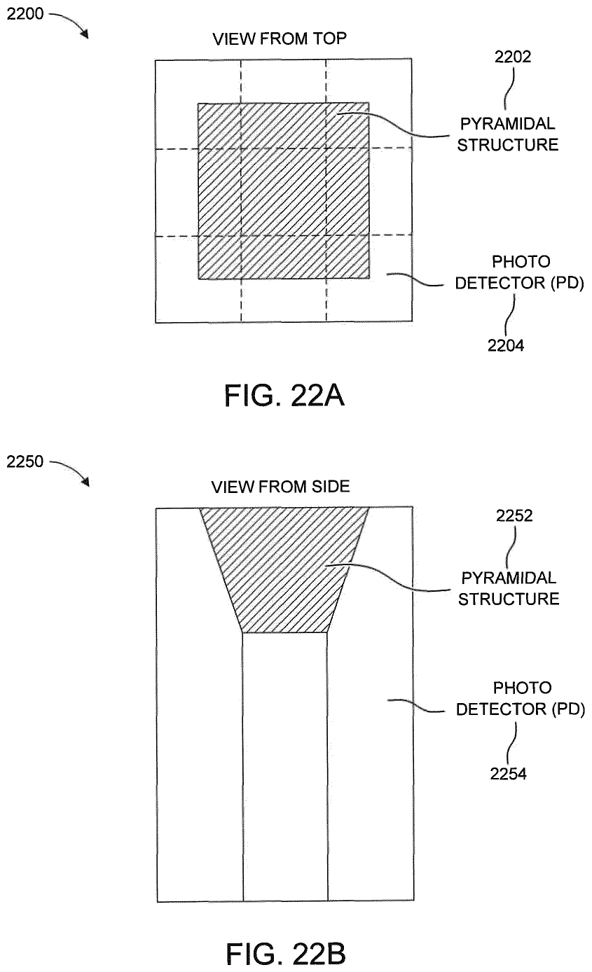

FIG. 22A is a schematic plan view illustrating an example pyramid (e.g., an inverted pyramid) for a nona pixel sensor configuration according to some embodiments. FIG. 22B is a schematic side view illustrating an example pyramid for a nona pixel sensor configuration according to some embodiments. For some embodiments, a pyramid shape 2202, 2252 may be used with nona pixel plenoptic sensor, such as a 3×3 grid of square subpixels 2204, 2254, in which the tip of a pyramid shape is centered on the center subpixel for some embodiments. For some embodiments, the tip or top of the pyramid may be a flat plateau. For some embodiments, the tip of the pyramid may be configured to match the area of the center subpixel. An example of such a configuration is shown in FIGS. 22A and 22B for some embodiments.

An angle of 54.7° was used with the analysis described herein because such an angle is the natural angle of silicon when using wet etching. Alternatively, other angles may be used. For example, greyscale lithography may be used for some embodiments. For some embodiments, a non-straight face, such as the examples shown in FIGS. 23C and 23D for some embodiments and described below, may be used with the pyramid shape. For some embodiments, the pyramid shape may be adapted according to the shape of the microlens (e.g., via diameter or via radius of curvature of the microlens). For some embodiments, the pyramid shape may be adapted to address a manufacturing constraint. For example, one or more of the layers of a pixel apparatus may be adjusted (or minimized), such as the height of the planarization, color filter, or other layer. Furthermore, a passivation process may be used to reduce the reactivity of one of more surfaces of a pixel sensor apparatus.

For some embodiments, the plenoptic subpixel sensors may be arranged in a 3×3 grid, and the pyramid shape may be centered on a center of the 3×3 grid. For some embodiments, the pyramid shape may be a frustum, and the flat top of the frustum may be configured to match a center subpixel sensor of the 3×3 grid. For example, the pyramid shape may be symmetrical and centered around the center subpixel sensor of the 3×3 grid for some embodiments. In some embodiments, the tip of the pyramid shape is a square. For example, the tip of the pyramidal structure may be clipped so that the tip is a square. The square tip may correspond to a square center subpixel sensor of a 3×3 grid of subpixels. For some embodiments, the pyramid portion of the pyramid shape may be a polygon extruded in at least one direction.

FIG. 23A is a schematic plan view illustrating an example pyramid for a 45° square based pyramidal structure according to some embodiments. The pyramidal structure 2302 may be symmetrical and centered around the center of the pixel for some embodiments. The pyramidal structure may be rotated 45° in comparison with the orientation of the subpixels 2304, the boundaries of which are indicated by the dashed lines.

FIG. 23B is a schematic plan view illustrating an example pyramid for a disk based pyramidal structure according to some embodiments. The pyramidal structure 2322 may be symmetrical and centered around the center of the pixel for some embodiments. For some embodiments, the pixel may include four subpixels 2324. The pyramidal structure may be a cone with the tip of the cone centered on the center of the pixel for some embodiments.

FIG. 23C is a schematic side view illustrating an example pyramid for a pyramidal structure with a curved convex facet according to some embodiments. The pyramidal structure 2342 may be symmetrical and centered around the center of the pixel for some embodiments. For some embodiments, the pixel may include four subpixels 2344. The pyramidal structure may have curved convex facets for some embodiments. The base of the pyramidal structure (not shown) may be a square or a circular disk for some embodiments.

FIG. 23D is a schematic side view illustrating an example pyramid for a pyramidal structure with a curved concave facet according to some embodiments. The pyramidal structure 2362 may be symmetrical and centered around the center of the pixel for some embodiments. For some embodiments, the pixel may include four subpixels 2364. The pyramidal structure may have curved concave facets for some embodiments. The base of the pyramidal structure (not shown) may be a square or a circular disk for some embodiments.

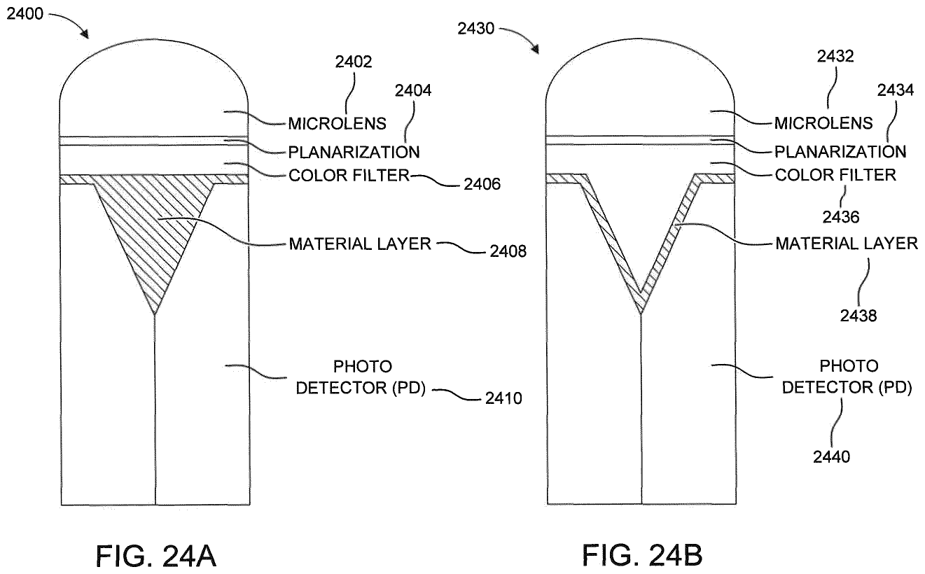

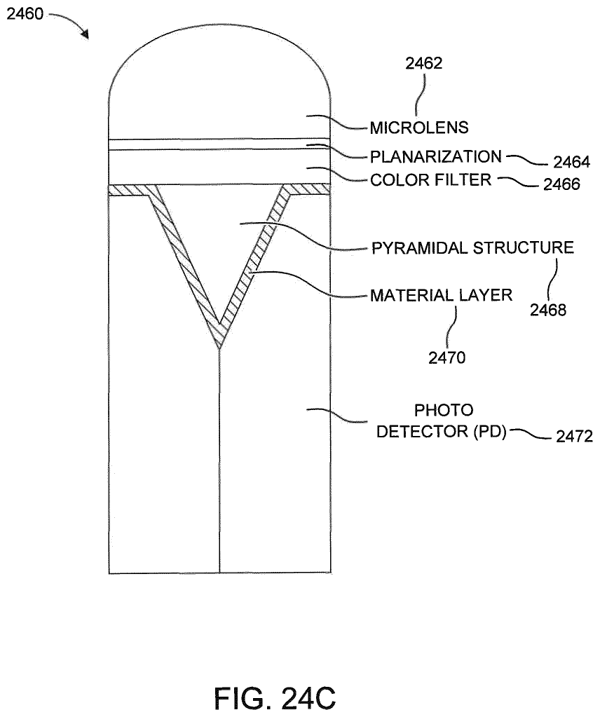

FIG. 24A is a schematic side view illustrating an example quad pixel with a material layer with a pyramidal structure according to some embodiments. For some embodiments, the material layer 2408 may include a pyramidal structure (or shape) as shown in FIG. 24A. For some embodiments, the material layer (which may be called a passivation layer or an oxide layer in some embodiments) may include a flat plane section with a thickness attached to a pyramid shape. The material layer may be filled with an inorganic material, such as, e.g., hafnium oxide, aluminum oxide, tantalum oxide, and/or silicon oxide for some embodiments. For some embodiments, a pixel structure 2400 may include a microlens 2402, a planarization layer 2404, a color filter 2406, a material layer 2408, and one or more photo detectors 2410 as shown in FIG. 24A.

FIG. 24B is a schematic side view illustrating an example quad pixel with a color filter with a pyramidal structure according to some embodiments. In some embodiments, the material layer may follow a pyramidal structure (or shape) with a thickness as shown in FIG. 24B. For some embodiments, the color filter may include a pyramid shape as shown in FIG. 24B. In some embodiments, the color filter may include a flat plane section with a thickness attached to a pyramid shape. For some embodiments, the material layer may be filled with an inorganic material, such as, e.g., hafnium oxide, aluminum oxide, tantalum oxide, and/or silicon oxide. For some embodiments, a pixel structure 2430 may include a microlens 2432, a planarization layer 2434, a color filter 2436, a material layer 2438, and one or more photo detectors 2440 as shown in FIG. 24B.

FIG. 24C is a schematic side view illustrating an example quad pixel with a color filter, a material layer, and a pyramidal structure according to some embodiments. In some embodiments, the material layer may follow a pyramidal structure (or shape) with a thickness as shown in FIG. 24C. For some embodiments, the material layer may be filled with silicon dioxide (SiO₂). In some embodiments, a separate pyramidal structure may be used with the material layer that follows a pyramid with a thickness as shown in FIG. 24C. The pyramidal structure, the material layer, and the color filter may each be a different material than the other two layers for some embodiments. For some embodiments, the pyramidal structure may be filled with an inorganic material, such as, e.g., hafnium oxide, aluminum oxide, tantalum oxide, and/or silicon oxide, and the color filter and the material layer may each be filled with color filter resin. For some embodiments, a pixel structure 2460 may include a microlens 2462, a planarization layer 2464, a color filter 2466, a pyramidal structure 2468, a material layer 2470, and one or more photo detectors 2472 as shown in FIG. 24C.

For some embodiments, the pyramidal structure may include a material layer above the silicon layer. For some embodiments, the pyramidal structure may include a color filter layer of the color filter system above the material layer. For some embodiments, the color filter layer may include a color filter resin. For some embodiments, the material layer may include an oxide layer between the color filter system and at least one of the two or more plenoptic subpixel sensors. For some embodiments, the pyramidal structure may be made of silicon dioxide (SiO₂).

An example apparatus in accordance with some embodiments may include a microlens; and two or more plenoptic subpixel sensors, the two or more plenoptic subpixel sensors including two or more photodiodes formed in a silicon layer, wherein a pyramidal structure is etched in the two or more respective silicon photodiodes formed in the silicon layer.

For some embodiments of the example apparatus, the pyramidal structure may be formed to generate an optical prism deviating light away from a center of the two or more plenoptic subpixel sensors.

For some embodiments of the example apparatus, the pyramidal structure may be configured to reduce optical crosstalk between at least two of the two or more plenoptic subpixel sensors.

For some embodiments of the example apparatus, the pyramidal structure may be configured to increase sensitivity of at least one of the two or more plenoptic subpixel sensors.

For some embodiments of the example apparatus, the pyramidal structure may be configured to increase angular discrimination for light incident on the microlens at an angle near a chief ray angle of the microlens.

For some embodiments of the example apparatus, the pyramid structure may be configured to confine light to one of the two or more plenoptic subpixel sensors.

For some embodiments of the example apparatus, the pyramid structure may be configured to reflect light away from at least one of the two or more plenoptic subpixel sensors.

For some embodiments of the example apparatus, the silicon layer may be etched with a trench conforming to a deep trench isolation (DTI) structure.

For some embodiments of the example apparatus, a focal length of the microlens may be less than a threshold.

For some embodiments of the example apparatus, the two or more plenoptic sensors may include a dual pixel sensor; and the pyramidal structure may include a triangular structure.

For some embodiments of the example apparatus, the two or more plenoptic sensors may include a quad pixel sensor.

For some embodiments of the example apparatus, the pyramidal structure may include a material layer above the silicon layer.

For some embodiments of the example apparatus, the pyramidal structure may conform to pyramid-shaped trenches etched in the silicon layer.

Some embodiments of the example apparatus may further include a color filter system.

For some embodiments of the example apparatus, the pyramidal structure may include a material layer above the silicon layer; and the material layer may include an oxide layer between the color filter system and at least one of the two or more plenoptic subpixel sensors.

For some embodiments of the example apparatus, the pyramidal structure may further include a color filter layer of the color filter system above the material layer.

For some embodiments of the example apparatus, the color filter layer may include a color filter resin.

For some embodiments of the example apparatus, the color filter system may include a planarization layer and a color filter layer.

For some embodiments of the example apparatus, a horizontal facet angle of the pyramidal structure may be 54.7 degrees.

For some embodiments of the example apparatus, a base of the pyramidal structure may be equal to half of a diameter of the microlens.

For some embodiments of the example apparatus, the two or more plenoptic subpixel sensors may be arranged in a 2×1 grid, and the pyramidal structure may be centered on a line dividing the 2×1 grid in half.

For some embodiments of the example apparatus, the two or more plenoptic subpixel sensors may be arranged in a 2×2 grid, and the pyramidal structure may be centered on a center of the 2×2 grid.

For some embodiments of the example apparatus, the two or more plenoptic subpixel sensors may be arranged in a 3×3 grid, and the pyramidal structure may be centered on a center of the 3×3 grid.

For some embodiments of the example apparatus, the pyramidal structure may be a frustum, and a flat top of the frustum may be configured to match a center subpixel sensor of the 3×3 grid.

For some embodiments of the example apparatus, a tip of the pyramidal structure may be a square.

For some embodiments of the example apparatus, a base of the pyramidal structure may be a disk.

For some embodiments of the example apparatus, a tip of the pyramidal structure may be a disk.

For some embodiments of the example apparatus, the two or more plenoptic subpixel sensors may be arranged in a grid array, and the pyramidal structure may be centered on a center of the grid array.

For some embodiments of the example apparatus, a pyramid portion of the pyramidal structure may be a triangle extruded in at least one direction.

For some embodiments of the example apparatus, a pyramid portion of the pyramidal structure may be a polygon extruded in at least one direction.

For some embodiments of the example apparatus, a base of a pyramid portion of the pyramidal structure may be a square.

Some embodiments of the example apparatus may further include one or more external insulators adjacent to an external edge of at least one of the plenoptic subpixel sensors.

For some embodiments of the example apparatus, the microlens may be configured to shift a chief ray angle corresponding to a pixel offset of two pixels.

For some embodiments of the example apparatus, at least one of the two or more plenoptic subpixel sensors may be adjacent to the color filter system.

Some embodiments of the example apparatus may further include an oxide layer, wherein the oxide layer may be adjacent to the color filter system, wherein at least one of the two or more plenoptic subpixel sensors may be adjacent to the oxide layer, and wherein the oxide layer may be between the color filter system and at least one of the two or more plenoptic subpixel sensors.

For some embodiments of the example apparatus, a base of a pyramid portion of the pyramidal structure may be adjacent to the oxide layer.

For some embodiments of the example apparatus, a size of a base of a pyramid portion of the pyramidal structure may be adjusted based on a curvature of the microlens.

For some embodiments of the example apparatus, the pyramidal structure may be symmetrical along a first plane cutting through a center of the pyramidal structure, the pyramidal structure may be symmetrical along a second plane cutting through the center of the pyramidal structure, and wherein the first plane may be perpendicular to the second plane.

For some embodiments of the example apparatus, wherein the color filter system may be adjacent to the microlens.

For some embodiments of the example apparatus, two or more plenoptic subpixel sensors may be adjacent to the color filter system.

For some embodiments of the example apparatus, the color filter system may include a filter pattern of two or more subpixels.

For some embodiments of the example apparatus, the pyramidal structure may include silicon dioxide (SiO₂).

For some embodiments of the example apparatus, the pyramidal structure may include silicon oxide.

For some embodiments of the example apparatus, the pyramidal structure may be configured to reduce optical crosstalk between at least two pixels.

For some embodiments of the example apparatus, the pyramidal structure may be configured to reduce optical crosstalk between at least two microlenses.

Note that various hardware elements of one or more of the described embodiments are referred to as “modules” that carry out (i.e., perform, execute, and the like) various functions that are described herein in connection with the respective modules. As used herein, a module includes hardware (e.g., one or more processors, one or more microprocessors, one or more microcontrollers, one or more microchips, one or more application-specific integrated circuits (ASICs), one or more field programmable gate arrays (FPGAs), one or more memory devices) deemed suitable by those of skill in the relevant art for a given implementation. Each described module may also include instructions executable for carrying out the one or more functions described as being carried out by the respective module, and it is noted that those instructions could take the form of or include hardware (i.e., hardwired) instructions, firmware instructions, software instructions, and/or the like, and may be stored in any suitable non-transitory computer-readable medium or media, such as commonly referred to as RAM, ROM, etc.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs). A processor in association with software may be used to implement a radio frequency transceiver for use in a WTRU, UE, terminal, base station, RNC, or any host computer.

1. An apparatus comprising:
a microlens; and
two or more plenoptic subpixel sensors, the two or more plenoptic subpixel sensors comprising two or more photodiodes formed in a silicon layer,
wherein a pyramidal structure is etched in the two or more respective silicon photodiodes formed in the silicon layer.

2. The apparatus of claim 1, wherein the pyramidal structure is formed to generate an optical prism deviating light away from a center of the two or more plenoptic subpixel sensors.

3. The apparatus of claim 1, wherein the pyramidal structure is configured to reduce optical crosstalk between at least two of the two or more plenoptic subpixel sensors.

4. (canceled)

5. The apparatus of claim 1, wherein the pyramidal structure is configured to increase angular discrimination for light incident on the microlens at an angle near a chief ray angle of the microlens.

6-7. (canceled)

8. The apparatus of claim 1, wherein the silicon layer is etched with a trench conforming to a deep trench isolation (DTI) structure.

9. (canceled)

10. The apparatus of claim 1,
wherein the two or more plenoptic sensors comprise a dual pixel sensor, and
wherein the pyramidal structure comprises a triangular structure.

11. The apparatus of claim 1, wherein the two or more plenoptic sensors comprise a quad pixel sensor.

12. The apparatus of claim 1, wherein the pyramidal structure comprises a material layer above the silicon layer.

13. The apparatus of claim 1, wherein the pyramidal structure conforms to pyramid-shaped trenches etched in the silicon layer.

14. The apparatus of claim 1, further comprising a color filter system.

15. The apparatus of claim 14,
wherein the pyramidal structure comprises a material layer above the silicon layer, and
wherein the material layer comprises an oxide layer between the color filter system and at least one of the two or more plenoptic subpixel sensors.

16. The apparatus of claim 15, wherein the pyramidal structure further comprises a color filter layer of the color filter system above the material layer.

17. The apparatus of claim 16, wherein the color filter layer comprises a color filter resin.

18. The apparatus of claim 14, wherein the color filter system comprises a planarization layer and a color filter layer.

19. The apparatus of claim 14, wherein at least one of the two or more plenoptic subpixel sensors is adjacent to the color filter system.

20. The apparatus of claim 14,
further comprising an oxide layer,
wherein the oxide layer is adjacent to the color filter system,
wherein at least one of the two or more plenoptic subpixel sensors is adjacent to the oxide layer, and
wherein the oxide layer is between the color filter system and at least one of the two or more plenoptic subpixel sensors.

21-23. (canceled)

24. The apparatus of claim 14, wherein the color filter system comprises a filter pattern of two or more subpixels.

25-33. (canceled)

34. The apparatus of claim 1,
wherein the two or more plenoptic subpixel sensors are arranged in a grid array, and
wherein the pyramidal structure is centered on a center of the grid array.

35-37. (canceled)

38. The apparatus of claim 1, further comprising one or more external insulators adjacent to an external edge of at least one of the plenoptic subpixel sensors.

39-44. (canceled)

45. The apparatus of claim 1, wherein the pyramidal structure is configured to reduce optical crosstalk between at least two microlenses.
